(19) United States
(12) Patent Application Publication
(10) Pub. No.: US 2016/0197268 A1
(43) Pub. Date: Jul. 7, 2016

(54) MAGNETORESISTIVE EFFECT ELEMENT, MANUFACTURING METHOD OF MAGNETORESISTIVE EFFECT ELEMENT, AND MAGNETIC MEMORY

(71) Applicant: KABUSHIKI KAISHA TOSHIBA, Minato-ku (JP)

(72) Inventors: Megumi YAKABE, Kawasaki (JP); Yuichi OHSAWA, Yokohama (JP); Chikayoshi KAMATA, Kawasaki (JP); Saori KASHIWADA, Yokohama (JP); Junichi ITO, Yokohama (JP); Eiji KITAGAWA, Yokohama (JP)

(73) Assignee: KABUSHIKI KAISHA TOSHIBA, Minato-ku (JP)

(21) Appl. No.: 15/068,062

(22) Filed: Mar. 11, 2016

Related U.S. Application Data
(63) Continuation of application No. PCT/JP2015/057889, filed on Mar. 17, 2015.

(30) Foreign Application Priority Data
Mar. 18, 2014 (JP) 2014-055384

(51) Int. Cl. H01L 43/08; H01L 43/12; H01L 43/10; H01L 43/02; G11C 11/16

(52) U.S. Cl. CPC H01L 43/08; H01L 43/02; G11C 11/161; H01L 43/10; H01L 43/12

(57) ABSTRACT

According to one embodiment, a magnetoresistive effect element includes a first magnetic layer including a first magnetic element; second magnetic layer; an intermediate layer between the first magnetic layer and the second magnetic layer; and a sidewall layer having a laminated structure on a side face of the first magnetic layer. The sidewall layer includes a first layer disposed on the side face of the first magnetic layer and including a first element having an atomic number larger than an atomic number of the first magnetic element, and a second layer including a second element having an atomic number smaller than the atomic number of the first atomic element. The first layer is disposed between the first magnetic layer and the second layer.

### CROSS-REFERENCE TO RELATED APPLICATIONS

This application is a Continuation application of PCT Application No. PCT/JP2015/057889, filed Mar. 17, 2015 and based upon and claiming the benefit of priority from Japanese Patent Application No. 2014-055384, filed Mar. 18, 2014, the entire contents of all of which are incorporated herein by reference.

### FIELD

The present embodiment described herein relate generally to a magnetoresistive effect element, a manufacturing method of the magnetoresistive effect element, and a magnetic memory.

### BACKGROUND

Memory devices using magnetism such as hard disk drives (HDD) and magnetoresistive random access memory (MRAM) have been developed.

As a technology applied to MRAM, spin transfer switching has been studied as a data writing method of MRAM. The spin transfer switching is a technology that reverses the direction of magnetization of a magnetic substance by passing a current through the magnetic substance.

In the spin transfer switching, a magnetization state in the magnetic substance on a nano scale can easily be controlled by a local magnetic field and the value of a current to reverse the magnetization can also be made smaller in accordance with an increasingly finer structure of the magnetic substance.

By using the spin transfer switching, the development of MRAM in high storage density is being promoted. Thus, it is desirable that the magnetoresistive effect element as a memory element be formed in the element size of 30 nm or less.

With increasingly finer element sizes, the magnitude of damage generated inside a lateral portion of an element could pose a big problem to element characteristics when the element is processed. Currently, a film of, for example, metal oxide or silicon nitride is formed on the side face of an element after the element is processed as a protective film formed on the side face of the magnetoresistive effect element.

The influence of oxygen or moisture on the magnetoresistive effect element from outside is blocked by such protective films and deterioration of magnetic characteristics of a magnetic layer originating from oxygen or moisture is prevented.

### BRIEF DESCRIPTION OF THE DRAWINGS

FIG. 1 and FIG. 2 are diagrams illustrating an structural example of the basic configuration of the magnetoresistive effect element according to an embodiment;

FIG. 3 and FIG. 4 are diagrams illustrating the basic configuration of the magnetoresistive effect element according to an embodiment;

FIG. 5 is a diagram illustrating a structure example of a magnetoresistive effect element according to a first embodiment;

FIG. 6 and FIG. 7 are diagrams showing processes of a manufacturing method of the magnetoresistive effect element according to the first embodiment;

FIG. 8 and FIG. 9 are diagrams illustrating structure examples of the magnetoresistive effect element according to a second embodiment;

FIG. 10, FIG. 11 and FIG. 12 are diagrams showing processes of the manufacturing method of the magnetoresistive effect element according to the second embodiment;

FIG. 13 is a diagram illustrating a structure example of the magnetoresistive effect element according to a third embodiment;

FIG. 14, FIG. 15A, FIG. 15B and FIG. 16 are diagrams illustrating processes of the manufacturing method of the magnetoresistive effect element according to the third embodiment;

FIG. 17 and FIG. 18 are diagrams illustrating processes of the manufacturing method of the magnetoresistive effect element according to a fourth embodiment;

FIG. 19, FIG. 20 and FIG. 21 are diagrams illustrating processes of the manufacturing method of the magnetoresistive effect element according to the fifth embodiment;

FIG. 22 and FIG. 23 are diagrams illustrating structure examples of the magnetoresistive effect element according to a sixth embodiment;

FIG. 24 and FIG. 25 are diagrams showing modifications of the magnetoresistive effect element according to an embodiment; and

FIG. 26 and FIG. 27 are diagrams showing an application example of the magnetoresistive effect element according to an embodiment.

### DETAILED DESCRIPTION

In general, according to one embodiment, a magnetoresistive effect element includes a first magnetic layer in which a direction of magnetization is variable, the first magnetic layer including a first magnetic element; a second magnetic layer in which the direction of magnetization is invariable; an intermediate layer between the first magnetic layer and the second magnetic layer; and a sidewall layer having a laminated structure on a side face of the first magnetic layer. The sidewall layer includes a first layer disposed on the side face of the first magnetic layer and including a first element having an atomic number larger than an atomic number of the first magnetic element, and a second layer disposed on the first layer and including a second element having an atomic number smaller than the atomic number of the first magnetic element, the first layer disposed between the first magnetic layer and the second layer.

Hereinafter, magnetoresistive effect elements according to the embodiments will be described with reference to the drawings.

### [A] Basic Form

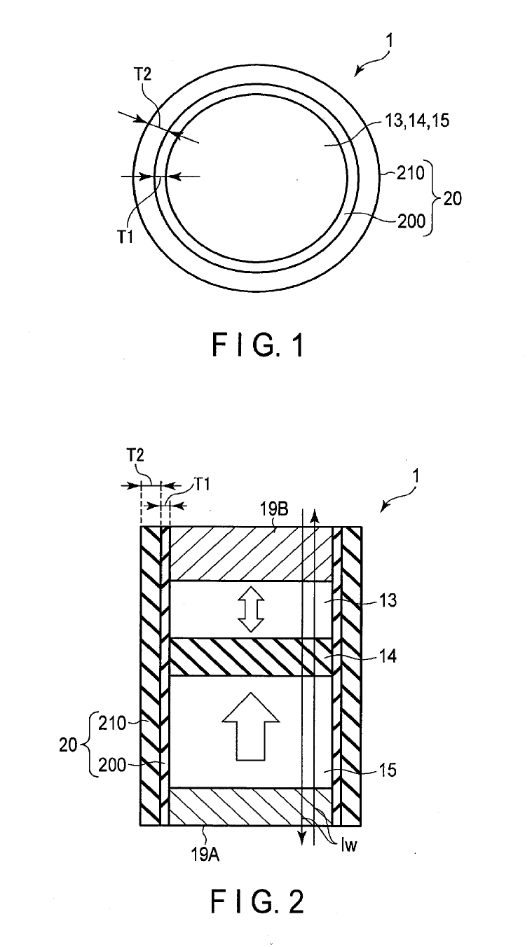

A basic form of the magnetoresistive effect element according to an embodiment will be described with reference to FIGS. 1 to 4.

FIG. 1 is a plan view showing a basic structure of a magnetoresistive effect element according to an embodiment. FIG. 2 is a sectional view showing the basic structure of the magnetoresistive effect element according to an embodiment.

As shown in FIGS. 1 and 2, a magnetoresistive effect element 1 according to an embodiment has a cylindrical structure.

The magnetoresistive effect element 1 includes a lower electrode 19A, an upper electrode 19B, two magnetic layers 13, 15 disposed between the lower electrode 19A and the upper electrode 19B, and an intermediate layer 14 disposed between the two magnetic layers 13, 15.

A magnetic tunnel junction is formed by the two magnetic layers 13, 15 and the intermediate layer 14 sandwiched therebetween. Hereinafter, the magnetoresistive effect element will also be called an MTJ element.

The direction of magnetization of the one magnetic layer 13 of the two magnetic layers is variable and the direction of magnetization of the other magnetic layer 15 is fixed (invariable). Hereinafter, the magnetic layer 13 in which the direction of magnetization is variable will be called a storage layer (or a recording layer or a magnetization free layer) and the magnetic layer 15 in which the direction of magnetization is fixed will be called a reference layer (or a fixed layer or a magnetization invariant layer). Arrows in the magnetic layers 13, 15 in FIG. 2 show the directions of magnetization of the magnetic layers 13, 15.

When a magnetization reversing current flowing in a direction perpendicular to a film surface of the magnetic layer 13 (lamination direction of the magnetic layer) is supplied to the magnetic layer 13, angular momentum of spin-polarized electrons generated by the current is transferred to the magnetization (spin) of the storage layer 13. The direction of magnetization (or spin) of the magnetic layer 13 is thereby reversed. That is, the direction of magnetization of the storage layer 13 is variable in accordance with the direction in which a current flows.

In contrast, the direction of magnetization of the reference layer 15 is fixed and invariable. That the direction of magnetization of the reference layer 15 is “invariable” or “fixed” means that when a magnetization reversing current to reverse the direction of magnetization of the storage layer 13 flows through the reference layer 15, the direction of magnetization of the reference layer 15 does not change.

In the magnetoresistive effect element 1, therefore, a magnetic layer of a large magnetization reversing current is used as the reference layer 15 and a magnetic layer of a smaller magnetization reversing current than that of the reference layer 15 is used as the storage layer 13. Accordingly, the magnetoresistive effect element 1 including the storage layer 13 in which the direction of magnetization is variable and the reference layer 15 in which the direction of magnetization is invariable is formed.

When magnetization reversal of the storage layer is caused by spin-polarized electrons, the magnitude of the magnetization reversing current (magnetization reversal threshold) thereof is determined based on the damping constant, coercive force, anisotropic magnetic force, and volume of the magnetic layer. Thus, a difference between the magnetization reversing current of the storage layer 13 and the magnetization reversing current of the reference layer 15 is provided by the above values being appropriately adjusted.

When the magnetization reversing current of the storage layer 13 is supplied to the magnetoresistive effect element (MTJ element), the direction of magnetization of the storage layer 13 changes in accordance with the direction in which the current flows and the relative magnetization arrangement of the storage layer 13 and the reference layer 15 changes. Accordingly, the magnetoresistive effect element 1 is in either a high resistance state (state in which the magnetization array is antiparallel) or a low resistance state (state in which the magnetization array is parallel).

As shown in FIG. 2, the storage layer 13 and the reference layer 15 have perpendicular magnetic anisotropy. The easy direction of magnetization of the storage layer 13 and the reference layer 15 is perpendicular to the film surface of the magnetic layer (lamination direction of the magnetic layer). In the easy direction of magnetization (magnetic anisotropy) perpendicular to the film surface, the magnetization oriented in a direction perpendicular to the film surface is called perpendicular magnetization.

Therefore, the magnetoresistive effect element 1 in the present embodiment is a magnetoresistive effect element of perpendicular magnetization type.

The easy direction of magnetization is a direction in which, when a ferromagnetic substance of a certain macro size is assumed, internal energy of the magnetic substance becomes the lowest if spontaneous magnetization is oriented in the direction in a state in which there is no external magnetic field. In contrast, a hard direction of magnetization is a direction in which, when a ferromagnetic substance of a certain macro size is assumed, internal energy of the magnetic substance becomes the highest if spontaneous magnetization is oriented in the direction in a state in which there is no external magnetic field.

The lower electrode 19A is disposed on an insulating film 80 on a substrate. The upper electrode 19B is disposed above the intermediate layer 14 via the magnetic layer (here, the storage layer 13).

In the present embodiment, a sidewall protective film (insulator) 20 is disposed on a side face of the MTJ element 1. The MTJ element 1 is covered with an interlayer insulating film (not shown) via the sidewall protective film 20.

The sidewall protective film 20 functions as a protective film that prevents impurities originating from outside the MTJ element 1 such as oxygen and moisture generated during the manufacturing process and composing elements of the interlayer insulating film from entering the MTJ element 1.

The sidewall protective film 20 on the magnetic layers 13, 15 included in the MTJ element 1 is an insulator in a laminated structure and includes at least two protective films (insulating films) 200, 210.

The protective films 200, 210 in the sidewall protective film 20 are laminated in a direction parallel to the film surface of a film to form the magnetic layer (direction perpendicular to the lamination direction of a plurality of magnetic layers). The first protective film 200 of the laminated protective films 200, 210 is in contact with the side faces of the magnetic layers 13, 15. The second protective film 210 of the laminated protective films 200, 210 is disposed on the surface (second surface) opposite to the surface (first surface) on the magnetic layer side of the first protective film 200.

Thus, the first protective film 200 is disposed between the second protective film 210 and the magnetic layers 13. 15. The second protective film 210 is interposed between the first protective film 200 and the interlayer insulating film.

The protective film 200 on the magnetic layer side (inner side) among a plurality of the protective layers 200, 210 inside the sidewall protective film 20 in the laminated structure is a film (for example, an insulating film) including an element heavier than the element (magnetic element) to be the main component of the magnetic layer forming the MTJ element as the main component.

The protective film 210 on the opposite side of the magnetic layer side (the outer side or interlayer insulating film side) among the plurality of protective layers 200, 210 inside the sidewall protective film 20 in the laminated structure is a film (for example, an insulating film) including an element lighter than the element to be the main component of the magnetic layer forming the MTJ element as the main component.

Hereinafter, an element having magnetism to form a magnetic layer such as the storage layer 13 and the reference layer 15 will be called a magnetic element.

An element lighter than a certain element (here, a magnetic element) is an element having an atomic number smaller than that of the certain element and an element heavier than a certain element is an element having an atomic number larger than that of the certain element.

In the present embodiment, the main component of a layer (material) means the element whose ratio is the largest among one or more elements (for example, solid elements at ordinary temperature and atmospheric pressure) constituting the layer. In the present embodiment, the ratio of each element in the layer (material) is determined in terms of atomic percent.

For example, the storage layer 13 is formed from a magnetic substance including an element in the fourth period (from the atomic number 19 to the atomic number 36).

In this case, the protective film 200 on the inner side includes an element having an atomic number larger than the atomic number 37 as the main component. On the other hand, the protective film 210 on the outer side includes an element having an atomic number smaller than the atomic number 22 as the main component.

In the MTJ element 1 in an embodiment, a thickness T1 of the first protective film 200 in the sidewall protective film 20 in a laminated structure is thinner than a thickness T2 of the second protective film 210. The thicknesses T1, T2 of the first and second protective films 200, 210 are thicknesses in a direction parallel to the film surface of the film forming the magnetic layers 13, 15 (direction perpendicular to the lamination direction of the magnetic layers). The thicknesses of the magnetic layers 13, 15 and the thickness of the intermediate layer 14 are assumed to be the thicknesses in the lamination direction of the magnetic layers.

The diffusion of composing elements in a laminated structure in which a magnetic layer and a single-layer film including an element heavier than the magnetic element forming the magnetic layer as the main component are laminated and a layered laminated structure in which a magnetic layer and a single-layer film including an element lighter than the magnetic element forming the magnetic layer as the main component are laminated will be described.

A laminated structure in which an MgAlB layer is disposed on the top surface of a magnetic layer made of cobalt-iron-boron (CoFeB) is measured by SIMS. MgAlB is a compound including an element lighter than Co and Fe (element whose atomic number is smaller than those of magnetic elements) as the main component.

Also, a laminated structure in which an HfB layer is disposed on the top surface of a magnetic layer made of CoFeB is measured by SIMS. HfB is a compound including an element heavier than Co and Fe (element whose atomic number is larger than those of magnetic elements) as the main component.

When a film made of a material including an element (atom) lighter than the magnetic element (magnetic atom) forming the magnetic layer (for example, the storage layer) is directly deposited on the magnetic layer by the sputtering method (energy of sputtered particles is estimated to be a few to a few ten eVs) so as to be in direct contact with the magnetic layer, elements lighter than the magnetic element are implanted into the magnetic layer by sputtered particles. Thus, a region (mixing layer) in which atoms of layers outside the magnetic layer and constituent atoms of the magnetic layer are mixed is formed near the boundary between the magnetic layer and a film including an element (atom) lighter than the magnetic element (magnetic atom) as the main component.

On the other hand, if a film made of a material including an element (atom) heavier than the magnetic element forming the magnetic layer as the main component is directly deposited on the magnetic layer, a region including the magnetic element and the heavy element is not formed inside the magnetic layer.

Therefore, it is desirable that a layer in direct contact with a magnetic layer be formed from a material including an element heavier than the magnetic element forming the magnetic layer as the main component to inhibit diffusion of impurities from the layer in contact with the magnetic layer into the magnetic layer.

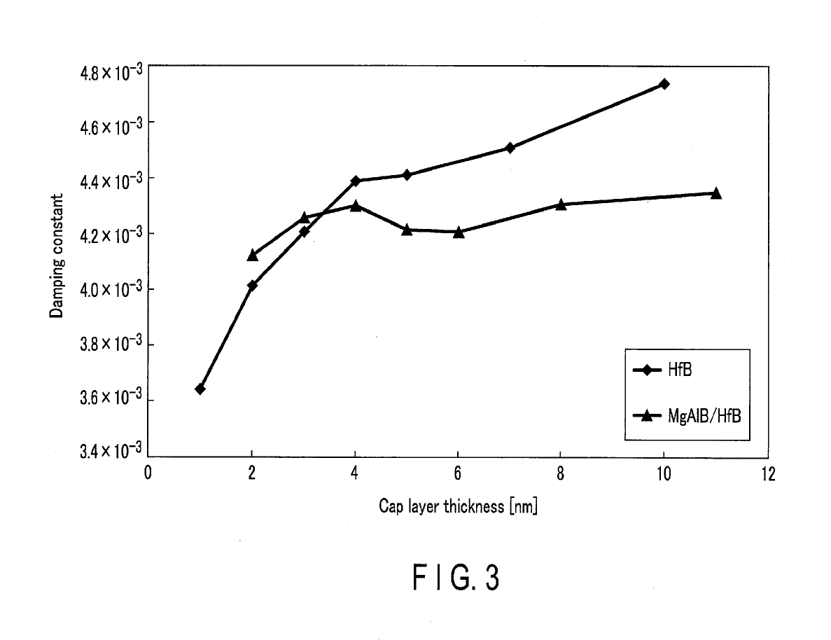

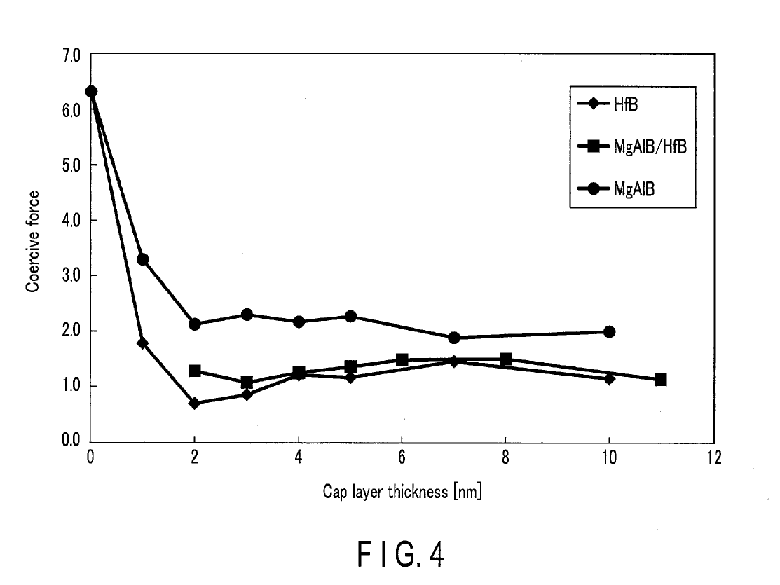

Magnetic characteristics of a magnetic layer in a laminated structure of the magnetic layer and a non-magnetic layer will be described using FIGS. 3 and 4.

In the present embodiment, when a multilayer film or a laminated structure (laminated structure) is denoted as a member A/member B, this indicates that the member A is stacked on the member B.

In measurements in FIGS. 3 and 4, a CoFeB film is used for the magnetic layer, a film including Hf as the main component is used as a film including an element heavier than the magnetic element as the main component, and a film including Mg, Al, and B is used as a film including an element lighter than the magnetic element as the main component.

Hereinafter, the non-magnetic layer on the CoFeB film in FIGS. 3 and 4 is also called a cap layer.

FIG. 3 is a graph showing a relationship between the thickness of a non-magnetic layer and the damping constant of a magnetic layer in a laminated structure of the magnetic layer and the non-magnetic layer.

The horizontal axis of FIG. 3 corresponds to the thickness T (unit: nm) of the non-magnetic layer and the vertical axis of FIG. 3 corresponds to the damping constant of the magnetic layer.

In FIG. 3, a measurement result of magnetic characteristics of a magnetic layer in a laminated structure (HfB/CoFeB) of the magnetic layer and a single-layer film including an element heavier than the magnetic element forming the magnetic layer as the main component is shown. In FIG. 3, a measurement result of magnetic characteristics of a magnetic layer in a laminated structure (MgAlB/HfB/CoFeB) of the magnetic layer, a layer including an element heavier than the magnetic element forming the magnetic layer as the main component, and a layer including an element lighter than the magnetic element forming the magnetic layer as the main component is shown. In a laminated structure of a layer including an element heavier than the magnetic element forming the magnetic layer as the main component and a layer including an element lighter than the magnetic element forming the magnetic layer as the main component, the layer including an element heavier than the magnetic element forming the magnetic layer as the main component is in contact with the magnetic layer.

In FIG. 3, concerning the MgAlB/HfB laminated film on the CoFeB film, the thickness of the HfB film in contact with the CoFeB film is fixed to 1 nm and the thickness of the MgAlB film is changed.

When, as shown in FIG. 3, a layer (here, the HfB film) including an element heavier than the magnetic element forming the magnetic layer as the main component is disposed on the magnetic layer, the damping constant of the magnetic layer tends to increase if the thickness of the layer including an element heavier than the magnetic element forming the magnetic layer as the main component increases.

If, for example, the thickness of the layer including an element heavier than the magnetic element forming the magnetic layer as the main component is 3 nm or more, an increase of the damping constant of the magnetic layer becomes more pronounced.

On the other hand, even if the thickness of a layer disposed on a layer including a heavy element as the main component and including an element lighter than the magnetic element forming the magnetic layer as the main component increases, an increase of the damping constant of the magnetic layer is inhibited.

From the above results, a layer including a heavy element as the main component desirably is a thin film having a thickness of 3 nm or less.

FIG. 4 is a graph showing the relationship between the thickness of the non-magnetic layer and a coercive force Hc of the magnetic layer in the laminated structure of the magnetic layer and the non-magnetic layer.

The horizontal axis of FIG. 4 corresponds to the thickness T (unit: nm) of the non-magnetic layer (cap layer) and the vertical axis of FIG. 4 corresponds to the coercive force Hc (unit: Oe) of the magnetic layer.

In FIG. 4, a measurement result of magnetic characteristics of a magnetic layer in a laminated structure (HfB/CoFeB) of the magnetic layer and a single-layer film including an element heavier than the magnetic element forming the magnetic layer as the main component and a laminated structure (MgAlB/CoFeB) of the magnetic layer and a single-layer film including an element lighter than the magnetic element forming the magnetic layer as the main component is shown.

Further in FIG. 4, a measurement result of magnetic characteristics of a magnetic layer in a laminated structure (MgAlB/HfB/CoFeB) of the magnetic layer, a layer including an element heavier than the magnetic element forming the magnetic layer as the main component, and a layer including an element lighter than the magnetic element forming the magnetic layer as the main component is shown. In a laminated structure of a layer including an element heavier than the magnetic element forming the magnetic layer as the main component and a layer including an element lighter than the magnetic element forming the magnetic layer as the main component, the layer including an element heavier than the magnetic element forming the magnetic layer as the main component is in contact with the magnetic layer.

In FIG. 4, the thickness of the CoFeB film of each sample is 2 nm. In FIG. 4, in the MgAlB/HfB laminated layer on the CoFeB film, the thickness of the HfB film in contact with the CoFeB film is fixed to 1 nm and the thickness of the MgAlB film is changed.

When, as shown in FIG. 4, a layer (here, the MgAlB film) including an element lighter than the magnetic element forming the magnetic layer as the main component is in contact with the magnetic layer, a mixing layer is formed in an interface between the layer including a light element as the main component and the magnetic layer. Accordingly, when compared with a case in which a layer (here, the HfB film) including an element heavier than the magnetic element as the main component is in contact with the magnetic layer, the coercive force of the magnetic layer tends to increase.

From the above results, a layer including a light element as the main component is desirably not in direct contact with the storage layer of an MTJ element.

When, as described above, a single-layer film including an element lighter than the magnetic element forming the magnetic layer as the main component is in direct contact with the magnetic layer, elements forming the single-layer film may diffuse into the magnetic layer. Also when a single-layer film including an element lighter than the magnetic element forming the magnetic layer as the main component is in direct contact with the magnetic layer, the coercive force of the magnetic layer may increase.

When a single-layer film including an element heavier than the magnetic element forming the magnetic layer as the main component is in direct contact with the magnetic layer, the damping constant of the magnetic layer may increase as the thickness of the single-layer film becomes thicker. If the thickness of the single-layer film including an element heavier than the magnetic element as the main component is made thinner to inhibit an increase of the damping constant of the magnetic layer, the capability of the single-layer film to protect the magnetic layer from outside factors (for example, oxygen and moisture) may be damaged. As a result, characteristics of the magnetic layer deteriorate.

Characteristics desirable for the magnetic layer of an MTJ element, for example, characteristics desirable for the storage layer include a small damping constant to reduce energy needed for magnetization reversal. It is also desirable that, like, for example, an example of the CoFeB film having a small coercive force shown in FIG. 4, an original coercive force of the magnetic layer be exhibited without deteriorating magnetic characteristics of the magnetic layer. Due to such characteristics, a write current (magnetization reversal threshold) can be reduced when an MTJ element is used as a memory element.

When a single-layer film made of a material including an element lighter than the magnetic element forming the magnetic layer as the main component or a single-layer film made of a material including an element heavier than the magnetic element forming the magnetic layer as the main component is in direct contact with the storage layer as a protective film to inhibit deterioration of the storage layer originating from oxygen or moisture, the storage layer may not be able to fully exhibit characteristics thereof due to an adverse effect originating from the protective film.

In addition, if the thickness of the single-layer film is made thinner to inhibit changes of magnetic characteristics caused by direct contact of each single-layer film, the capability of the single-layer film as a protective film may not be met thus magnetic characteristics of the magnetic layer may change due to oxygen or moisture.

In contrast, the insulating film (sidewall protective film) 20 to protect the magnetic layers on the inner side from outside factors such as oxygen and moisture generated during the manufacturing process in an MTJ element in the present embodiment has a laminated structure.

In the MTJ element in the present embodiment, the sidewall protective film 20 in the laminated structure includes the protective film 200 including an element heavier than the magnetic element forming the magnetic layer (element having an atomic number larger than that of the magnetic element) as the main component and the protective film 210 including an element lighter than the magnetic element forming the magnetic layer (element having an atomic number smaller than that of the magnetic element) as the main component.

The protective film 200 including an element heavier than the magnetic element as the main component is disposed between the magnetic layers 13, 15 and the protective film 210 including an element lighter than the magnetic element as the main component. The protective film 200 including an element heavier than the magnetic element as the main component is in direct contact with the magnetic layer (for example, the storage layer 13).

Accordingly, an MTJ element according to the present embodiment can prevent an increase of coercive force of the storage layer resulting from direct contact of the protective film 210 including an element lighter than the magnetic element as the main component with the magnetic layer and diffusion of elements included in the protective film 210 into the magnetic layer.

In an MTJ element according to the present embodiment, the thickness T1 of the protective film 200 including an element heavier than the magnetic element in the magnetic layer as the main component is thinner than the thickness T2 of the protective film 210 including an element lighter than the magnetic element inside the magnetic layer as the main component. The thickness T1 of the protective film 200 including an element heavier than the magnetic element as the main component is set to, for example, 3 nm or less. The MTJ element according to the present embodiment can thereby alleviate an increase of the damping constant of the storage layer 13 resulting from direct contact of the protective film 200 including an element heavier than the magnetic element as the main component with the storage layer 13.

The thickness T2 of the protective film 210 including an element lighter than the magnetic element as the main component is thicker than the protective film 200 and set to 20 nm or less (for example, about 5 nm). If the thickness of a film including a light element (for example, Al, Mg, or B) with a large quantity of adsorbed oxygen as the main component is thick, the stress applied to the magnetic layer by the film including a light element as the main component may increase. Thus, the thickness T2 of the protective film 210 including an element lighter than the magnetic element as the main component is preferably 20 nm or less.

In the present embodiment, the protective film 210 having a thick film thickness and including an element lighter than the magnetic element as the main component is disposed between an interlayer insulating film 81 and the thin protective film 200. In an MTJ element in the present embodiment, the insulating film 20 on the side face of the MTJ element (magnetic tunnel junction) can maintain the function as a protective film for the magnetic layer.

When, for example, a magnetic layer including at least one of iron (Fe) having the atomic number 26 and cobalt (Co) having the atomic number 27 as the magnetic element is used for the storage layer of the MTJ element, hafnium (Hf) is used as an element heavier than the magnetic element and at least one element selected from a group of carbon (C), magnesium (Mg), and aluminum (Al) is used as an element lighter than the magnetic element.

Hf, Mg, and Al are more likely to bond to oxygen than Fe and Co. Thus, by using Hf, Mg, for Al for the protective film, compared with a film including silicon (Si) as the main component, a good protective film can be formed that leads to minimal oxidation of the magnetic layer.

According to an embodiment, as described above, the magnetoresistive effect element can be protected from impurities from outside the element and characteristics of the magnetoresistive effect element can be improved.

In FIGS. 1 and 2, the sidewall protective film 20 in a two-layer structure is shown, but the sidewall protective film 20 in a three-layer structure may also be disposed on the side face of a laminated structure including the magnetic layers 13, 15.

The interface between the first and second protective films 200, 210 may not be steep and the change in composition in the interface between the first and second protective films 200, 210 may be gradual. In such a case, the sidewall protective film 20 has a structure similar to a structure in which a film including both of an element heavier than the magnetic element and an element lighter than the magnetic element is disposed between the film 200 including an element heavier than the magnetic element and the film 210 including an element lighter than the magnetic element.

Regarding the first protective film 200 including an element with an atomic number larger than that of the magnetic element (for example, an element having an atomic number larger than 37) as the main component in the sidewall protective film in a laminated structure, an element having an atomic number smaller than that of the magnetic element may be included in the first protective film 200 if the element is not the main component of the first protective film 200. Regarding the second protective film 210 including an element with an atomic number smaller than that of the magnetic element (for example, an element having an atomic number smaller than 22) as the main component, an element having an atomic number larger than that of the magnetic element may be included in the second protective film 210 if the element is not the main component of the second protective film 210.

### [B] First Embodiment

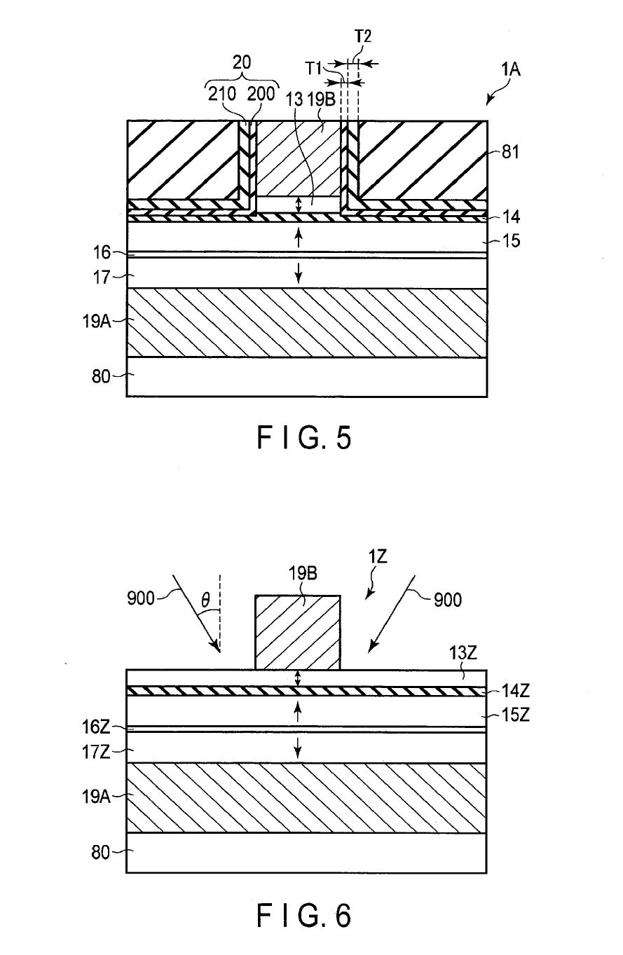

A magnetoresistive effect element according to the first embodiment and a manufacturing method thereof will be described with reference to FIGS. 5 to 7.

In the present embodiment, a configuration substantially the same as that of the magnetoresistive effect element in FIGS. 1 and 2 will be described when necessary.

(1) Structure

The structure of the magnetoresistive effect element (MTJ element) according to the first embodiment will be described using FIG. 5.

As shown in FIG. 5, an MTJ element 1A according to the first embodiment is disposed on a substrate 80 such as to be covered with an interlayer insulating film 81.

The MTJ element 1A according to the first embodiment includes a shift control layer 17, a spacer layer 16, a reference layer 15, an intermediate layer 14, a storage layer 13, and an insulator (sidewall protective film) 20 in a laminated structure.

The MTJ element 1A in FIG. 5 is a top free type (bottom pin type) MTJ element.

The shift control layer 17 is disposed on a lower electrode 19A on the substrate 80.

The reference layer 15 is laminated above the shift control layer 17 via the spacer layer 16.

The intermediate layer (tunnel barrier layer) 14 is laminated on the reference layer 15.

The storage layer 13 is laminated on the reference layer 15 via the intermediate layer 14.

An upper electrode 19B is laminated on the storage layer 13.

The shift control layer (also called a shift correction layer or a bias magnetic field layer) 17 is disposed next to the reference layer 15 to bring a magnetic field (shift magnetic field) from the reference layer 15 to the storage layer 13 closer to zero. The magnetization of the shift control layer 17 is fixed and the direction of magnetization of the shift control layer is set in the opposite direction of the direction of magnetization of the reference layer 15.

The lower electrode 19A is, for example, a layer serving both as a lower electrode and a leader line of a magnetoresistive effect element. The lower electrode 19A is preferably formed from a material having a low electric resistance and superior in diffusion resistance. The lower electrode 19A may have a function as a buffer layer to grow a flat magnetic layer of perpendicular magnetization.

In addition to the function as an electrode, the upper electrode 19B is also used as a mask (hard mask) for patterning the MTJ element 1A. Thus, the material used for the upper electrode 19S preferably has a low electric resistance, is superior in diffusion resistance, and has high etching resistance/milling resistance. However, the upper electrode 19B may be formed from a newly formed electric conductor after a member used as a hard mask during patterning is peeled off. For example, after the laminated structure is processed using a hard mask of carbon, carbon is peeled off by oxygen. An electrode material of low resistance such as gold is formed on an upper portion of the laminated structure from which the hard mask has been peeled off. The upper electrode 19B is thereby formed.

The sidewall protective film 20 as a protective film is disposed on the side face of the storage layer 13. The sidewall protective film 20 is an insulator having a laminated structure made of a plurality of films. The sidewall protective film 20 includes the two protective films 200, 210 having mutually different materials. The protective film 200 on the inner side of the sidewall protective film 20 in a laminated structure is disposed on the side face of the storage layer 13 and the protective film 210 on the outer side is disposed between the protective film 200 on the inner side and the interlayer insulating film 81.

To improve characteristics of the magnetic layer and the intermediate layer, an interface layer may be disposed near the interface between the storage layer 13 and the intermediate layer 14 and near the interface between the reference layer 15 and the intermediate layer 14.

In the example shown in FIG. 5, the dimension (diameter) of the storage layer 13 in a direction parallel to the substrate surface is smaller than the dimension of each layer below the storage layer 13 such as the intermediate layer 14, the reference layer 15, and the shift control layer 17. In this case, the sidewall protective film 20 is disposed on the side face of the storage layer 13 and also on the top surface of the intermediate layer 14. The sidewall protective film 20 is disposed on the side face of the layers 14, 15, 16, 17, and 19A below the storage layer 13 at an end of the intermediate layer 14 and the reference layer 15. In the manufacturing process of MTJ elements, the first protective film 200 may not be formed on the side face of the reference layer 15 so that the second protective film 210 is in contact with the side face of the reference layer 15.

The protective film 200 on the inner side (magnetic layer side, lower side) of the protective films 200, 210 in a laminated structure is in direct contact with the side face of the storage layer 13. The protective film 200 is in contact with the top surface and the side face of the intermediate layer 14. The protective film 200 is in contact with the side face of the intermediate layer 14, the reference layer 15, the spacer layer 16, and the shift control layer 17.

In the sidewall protective film 20 in a laminated structure, the thickness T1 of the first protective film 200 on the inner side (magnetic layer side) is thinner than the thickness T2 of the second protective film 210 on the outer side (interlayer insulating film side). For example, the thickness T1 of the first protective film 200 is 3 nm or less and the thickness T2 of the second protective film 210 is 3 nm to about 20 nm. The thickness of the second protective film 210 is preferably 20 nm or less (for example, about 5 nm). Incidentally, the thickness of the second protective film 210 may be thicker than 20 nm and may be, for example, about 30 nm.

The storage layer 13 is formed from a magnetic substance including an element in the fourth period (from the atomic number 19 to the atomic number 36). The storage layer 13 includes, for example, one or more elements selected from a group of manganese (Mn), iron (Fe), and cobalt (Co) as main components.

Instead of Mn, Fe, and Co, nickel (Ni) may be used as the magnetic element of the storage layer 13. The storage layer 13 may include, in addition to at least one of Mn, Fe, and Co, boron (B).

The storage layer 13 is formed using, for example, at least one of CoFeB and an Mn alloy. The storage layer 13 is a single-layer film or a laminated film including CoFeB. Alternatively, the storage layer 13 is a single-layer film or a laminated film including the Mn alloy. The storage layer 13 may also be a combination of CoFeB and the Mn alloy, for example, a laminated film including CoFeB and the Mn alloy.

As the material of the reference layer 15, at least one material selected from a ferromagnetic material having a L1₀ structure or a L1₁ structure such as FePd, FePt, CoPd, CoPt and the like, a soft magnetic material such as CoFeB, a ferrimagnetic material such as TbCoFe, and an Mn alloy is used. The reference layer 15 may also be an artificial lattice formed from a magnetic material (for example, NiFe, Fe, Co or the like) and a non-magnetic material (Cu, Pd, Pt or the like).

As the material of the intermediate layer 14, an insulating material such as magnesium oxide (MgO), magnesium nitride (MgN), aluminum oxide (Al₂O₃), aluminum nitride (AlN), or a laminated film thereof is used. For example, the intermediate layer 14 is formed from an insulating film including MgO as the main component. A non-magnetic metal or a non-magnetic semiconductor may also be used for the intermediate layer 14.

For example, the shift control layer 17 is formed from the same material as that of the reference layer 15. The spacer layer 16 between the reference layer 15 and the shift control layer 17 is formed from a metal such as ruthenium (Ru) and Ta.

The lower electrode 19A has a laminated structure including a metal layer of tantalum (Ta), copper (Cu), ruthenium (Ru), iridium (Ir) or the like. For the upper electrode 19B, for example, Ta is used.

The first protective film 200 on the inner side in contact with the magnetic layer of the sidewall protective film (insulator) 20 in a laminated structure is a film including an element heavier than the magnetic element (element having an atomic number larger than that of the magnetic element) forming the magnetic layer (here, the storage layer). The second protective film 210 on the outer side not in contact with the magnetic layer of the sidewall protective film 20 in laminated structure is a film including an element lighter than the magnetic element (element having an atomic number smaller than that of the magnetic element) forming the magnetic layer.

If the magnetic layer has, for example, a magnetic element belonging to the fourth period as the main component, the first protective film 200 inside the sidewall protective film 20 is formed from an insulating material including an element (first element) having an atomic number larger than 37 as the main component. An element having an atomic number smaller than 22 may be included in the first protective film 200 if the element is not the main element of the first protective film 200.

For example, the first protective film 200 is formed from an insulating material including hafnium (Hf). In the first protective film 200, Hf becomes the main component of the protective film (for example, an insulating compound). As a concrete example, the first protective film 200 is made of a film selected from an HfBO film, HfAlBO film, ScHfBO film, HfBN film, HfAlBN film, ScHfBN film, HfBON film, HfAlBON film, and ScHfBON film. In addition, the first protective film 200 may also be an oxide, nitride, or oxynitride including at least one element selected from niobium (Nb), zirconium (Zr), tantalum (Ta) and tungsten (W) as the main component. Further, the first protective film 200 may be a film including B (boron) in an oxide, nitride, or oxynitride including Nb, Zr, Ta, or W as the main component.

If the magnetic layer has, for example, a magnetic element belonging to the fourth period as the main component, the second protective film 210 inside the sidewall protective film 20 is formed from an insulating material including an element (second element) having an atomic number smaller than 22 as the main component. An element having an atomic number larger than 37 may be included in the second protective film 210 if the element is not the main element of the second protective film 210.

For example, the second protective film 210 is formed from an insulating material including at least one element selected from magnesium (Mg), aluminum (Al), and carbon (C). In the second protective film 210, at least one element selected from Mg, Al, and C becomes the main component. As a concrete example, the second protective film 210 is made of a film selected from a C film, MgAlBO film, AlBO film, ScAlBO film, MgAlBN film, CN film, MgAlBN film, AlBN film, ScAlBN film, MgAlBON film, AlBON film, ScAlBON film, CAIN film, CAlO film, CAlSiO film, and CAlSiN film.

(2) Manufacturing Method

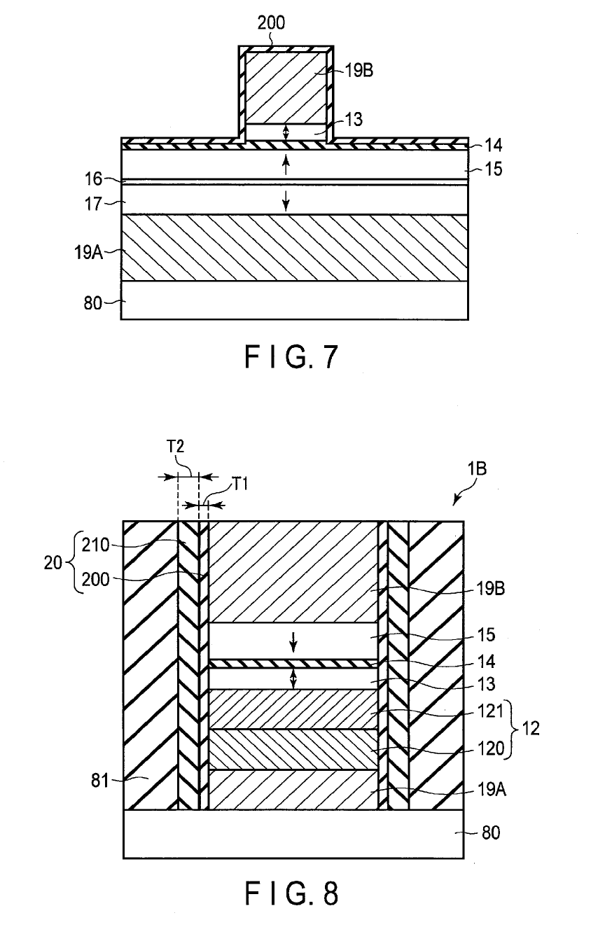

The manufacturing method of a magnetoresistive effect element (MTJ element) according to the first embodiment will be described using FIGS. 6 and 7. Here, the manufacturing method of an MTJ element in the present embodiment will be described using also FIG. 5 when appropriate.

FIGS. 6 and 7 are cross-sectional process charts illustrating each process of the manufacturing method of an MTJ element according to the present embodiment.

As shown in FIG. 6, the conductive layer 19A to be a lower electrode is deposited on the substrate 80 by, for example, the sputtering method.

A magnetic layer (shift control layer) 17Z, a conductive layer (spacer layer) 16Z, a magnetic layer (reference layer) 15Z, an insulating layer (intermediate layer) 14Z, a magnetic layer (storage layer) 13Z, and the conductive layer 19B are successively deposited on the conductive layer 19A from the substrate side using the sputtering method, the ALD method or the like. Accordingly, a laminated structure (layer to be processed) 1Z to form a top free type MTJ element is formed on the substrate 80.

The conductive layer 19B on the magnetic layer 13Z is processed into a predetermined shape (for example, a cylindrical shape) by lithography and etching and the mask (hard mask) 19B to process the laminated structure 1Z including the magnetic layers 13Z, 15Z, 17Z is thereby formed in an upper portion of the laminated structure 1Z.

Milling of the laminated structure 1Z is performed using the hard mask 19B as a mask.

The milling to process the laminated structure 1Z is ion milling using an inert gas such as argon (Ar), krypton (Kr), or xenon (Xe). In the present embodiment, the laminated structure 1Z is processed by the ion milling using Ar. The laminated structure 1Z may also be processed by etching using a gas cluster ion.

An incidence angle θ of ions (ion beam) 900 with the laminated structure 1Z in the ion milling is set to, for example, about 50° when the direction perpendicular to the film surface of the layer to be processed included in the laminated structure 1Z (substrate surface) is set as a reference angle (0°). Hereinafter, the ion milling in which the film surface of the layer to be processed is irradiated with an ion beam from a direction inclined with respect to the film surface (substrate surface) will be called inclined ion milling.

The ion milling is performed using, as a stopper, the top surface of the insulating film 14Z as an intermediate layer. Accordingly, as shown in FIG. 7, the storage layer 13 having a shape corresponding to the pattern of the hard mask 19B is formed on the insulating film 14.

The first protective film 200 having the predetermined thickness T1 (for example, 3 nm or less) is formed by the sputtering method such as to cover the processed storage layer 13. The first protective film 200 in contact with the storage layer 13 is formed from a material including an element heavier than the magnetic element of the storage layer 13 as the main component.

The first protective film 200 on the storage layer 13 is made of an insulating material including an element (for example, Hf) having an atomic number larger than 37 as the main component. The first protective film 200 is formed from a material selected from, for example, HfBO, HfAlBO, ScHfBO, HfBN, HfAlBN, ScHfBN, HfBON, HfAlBON, and ScHfBON.

For example, while the storage layer 13 is etched for processing, the top surface of the intermediate layer 14 may, recede to the substrate 80 side due to over-etching. In such a case, as shown in FIG. 7, the first protective film 200 covers the side face on the upper portion side (portion immediately below the storage layer 13) of the intermediate layer 14.

As shown in FIG. 5, the second protective film 210 is formed on the first protective film 200 by the sputtering method so as to have the thickness T2 (for example, 5 nm to about 20 nm), which is thicker than the thickness of the first protective film 200. The second protective film 210 (protective film not in contact with magnetic layer) on the first protective film 200 is made of an insulating material including an element with an atomic number smaller than 22 (for example, at least one of C, Mg, and Al) as the main component. The second protective film 210 is formed from a material selected from, for example, C, MgAlBO, AlBO, ScAlBO, MgAlBN, CN, MgAlBN, AlBN, ScAlBN, MgAlBON, AlBON, ScAlBONCAlN, and CAlO.

The first and second protective films 200, 210 may be formed by using the ion beam sputtering method, ion plating, vacuum evaporation, ALD method, or vacuum film formation technology such as the CVD method. Further, for the first and second protective films 200, 210 deposited by the above methods, natural oxidation, or oxidation treatment or nitriding may be performed to the deposited protective films 200, 210 by oxygen plasma or nitrogen plasma to insulate the films more thoroughly. For example, oxidation treatment to the protective films 200, 210 is performed by exposure of the laminated structure to the atmosphere, oxidation treatment in a vacuum, radical oxidation treatment, plasma oxidation treatment, or treatment using an oxygen cluster ion. Nitriding to the protective films 200, 210 is performed by radical nitriding, plasma nitriding, or treatment using a nitrogen cluster ion. Oxidation treatment or nitriding to the protective films 200, 210 may be performed in units of layers.

Also, the first and second protective films 200, 210 may be formed by a film (for example, a conductor film or semiconductor film) formed on the layer to be processed (laminated structure including magnetic layers) in a state including no oxygen or nitrogen being insulated by the above oxidation treatment or nitriding.

Oxide, nitride, or oxynitride forming the sidewall protective film 20 only needs to ensure insulating properties without depending on a valence state (composition ratio) of composing elements of the oxide/nitride.

If each layer below the intermediate layer 14Z is processed before the first and second protective films 200, 210 are formed, the first and second protective films 200, 210 are deposited on the side face of the processed layers 14Z, 15Z, 16Z, 17Z. If each layer below the intermediate layer 14 is processed after the first protective film 200 is deposited, the second protective film 210 is deposited on the side face of the processed layers 15, 16, 17.

After the MTJ element in the predetermined shape is formed by processing the laminated structure, the interlayer insulating film 81 is deposited on the substrate 80 by, for example, the CVD method such as to cover the MTJ element including the sidewall protective film 20 in a laminated structure.

When the interlayer insulating film 81 is deposited, the protective film 210 having a relatively thick film thickness (for example, thicker than 3 nm and equal to 20 nm or less) is 0.5 present on the protective film 200 having a relatively thin film thickness (for example, 3 nm or less). Thus, even if the protective film 200 in contact with the magnetic layers 13, 15 has a thin film thickness, the sidewall protective film 20 in a laminated structure can prevent oxygen or moisture generated when the interlayer insulating film 81 is deposited from intruding into the magnetic layers 13, 15 after infiltrating through the sidewall protective film 20 as a protective film.

With the above manufacturing process, an MTJ element according to the first embodiment is formed.

(3) Effect

Heretofore, damage applied to the side face of magnetic layers of an MTJ element when an insulating film as a protective film is formed has not been mentioned.

However, depending on the material used for the protective film, there is the possibility of an adverse effect of implantation and diffusion of composing elements of the protective film into the element when the protective film is formed and an adverse effect of an increasing damping constant of the storage layer caused by contact of the protective film and the magnetic layer. Thus, the development of a material minimizing an adverse effect generated when the protective film is formed and an adverse effect on the magnetic layer originating from the protective film itself and capable of effectively protecting an element is desired.

An MTJ element according to the present embodiment can prevent deterioration (corrosion) of the magnetic layer originating from impurities from outside by the sidewall protective film 20 in a laminated structure including the first and second protective films 200, 210 without causing degradation of characteristics of the magnetic layer originating from the sidewall protective film 20.

For example, the first and second protective films 200, 210 are films including elements (for example, Mg, Al, and Hf) more likely to be oxidized than composing elements (for example, Co and Fe) of the magnetic layer. Therefore, a high-quality insulating film highly capable of protecting the magnetic layer while inhibiting oxidization of the magnetic layer can be formed.

According to the first embodiment, the first protective film 200 formed on the side face of the MTJ element 1A has an element heavier than the magnetic element (element having an atomic number larger than that of the magnetic element) constituting the storage layer 13 and the reference layer 15 as the main component. An element heavier than the magnetic element is less likely to be diffused into the magnetic layer than an element lighter than the magnetic element. The influence of the weight of an atom is conspicuous particularly for sputtered particles (particles having energy of a few eVs to a few ten eV) caused to fly by the sputtering phenomenon and even if sputtered particles collide against heavy elements, heavy elements are less likely to be implanted in another member.

Therefore, the present embodiment can prevent diffusion of an element lighter than the magnetic element into the magnetic layer generated when a film including an element lighter than the magnetic element as the main component is in contact with the magnetic layer. As a result, the present embodiment can inhibit deterioration of the magnetic layer.

In the present embodiment, the protective film 200 including an element heavier than the magnetic element is present between the magnetic layer and the protective film 210 including an element lighter than the magnetic element (element having an atomic number smaller than that of the magnetic element) included in the magnetic layer as the main component. In the present embodiment, changes of the coercive force of the magnetic layer when a film including an element lighter than the magnetic element is in contact with the magnetic layer can thereby be inhibited.

In addition, the thickness T1 of the film 200 including an element heavier than the magnetic element constituting the storage layer 13 and the reference layer 15 is thin. Therefore, in the present embodiment, an increase of the damping constant of the magnetic layer resulting from an increased film thickness of the film 200 including an element heavier than the magnetic element can be inhibited.

Thus, in the present embodiment, an increase of the coercive force of the magnetic layer and the damping constant can be inhibited and therefore, a write current of the MTJ element can be reduced.

Also in the present embodiment, the protective film 210 made of elements that are easily oxidized and having a thick film thickness is disposed between the thin insulating film (protective film) 200 and the interlayer insulating film 81.

Accordingly, in the present embodiment, even if the thickness of the insulating film (protective film) 200 is made thinner to reduce an adverse effect on the magnetic layer, constituent atoms of the films 210, 81 deposited after the protective film 200 is formed can be prevented from intruding into the magnetic layer.

According to the magnetoresistive effect element and the manufacturing method thereof in the present embodiment, as described above, the magnetic layer can be protected from external factors during the manufacturing process and element characteristics of the MTJ element can be improved.

### [C] Second Embodiment

Hereinafter, a magnetoresistive effect element according to the second embodiment and a manufacturing method thereof will be described with reference to FIGS. 8 to 12.

In the present embodiment, the description of structural elements common to those in the first embodiment is provided when necessary.

(1) Structure

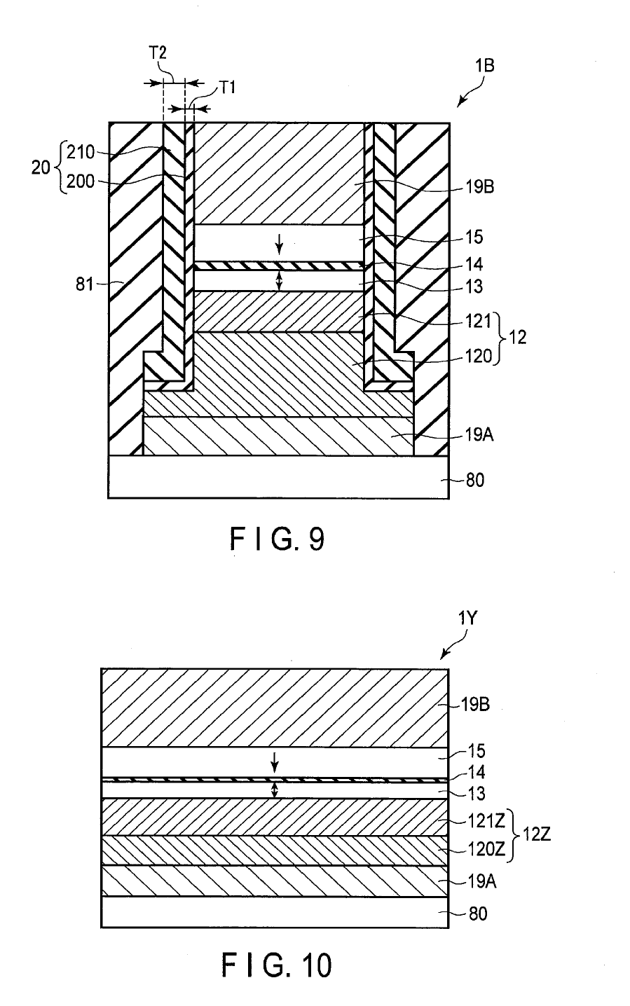

The structure of the magnetoresistive effect element (MTJ element) according to the second embodiment will be described using FIGS. 8 and 9.

FIG. 8 is a sectional view illustrating the structure of the MTJ element according to the present embodiment.

As shown in FIG. 8, an MTJ element 1B according to the present embodiment is a bottom free type (top pin type) MTJ element.

The MTJ element 1B successively includes a lower electrode 19A, an underlying layer 12, a storage layer 13, an intermediate layer 14, a reference layer 15, and an upper electrode 19B from the substrate side.

The MTJ element 1B includes a sidewall protective film 20 in a laminated structure disposed on the side face of the MTJ element. The sidewall protective film 20 includes a first protective film 200 and a second protective film 210. The first and second protective films 200, 210 are laminated on the side face of the MTJ element 1B in a direction parallel to the surface of a substrate 80.

The underlying layer 12 has a two-layer structure and includes a first layer (hereinafter, called a lower layer) 120 on the top surface of the lower electrode 19A and a second layer (hereinafter, called an upper layer) 121 on the top surface of the first layer 120.

The upper layer 121 of the underlying layer 12 in a laminated structure is in direct contact with the storage layer 13. The lower layer 120 of the underlying layer 12 is adjacent to a surface opposite to the surface on the storage layer 13 side of the upper layer 121.

A material having a small spin pumping effect is preferably used for the upper layer 121 of the underlying layer 12. The friction constant of the storage layer 13 is made smaller by a material having a small spin pumping effect being used for the film 120 in contact with the storage layer 13 so that the write current can be reduced. The upper layer 121 may also have a function to improve crystallinity of the storage layer 13.

FIG. 9 is a sectional view illustrating a modification of the MTJ element according to the present embodiment.

As shown in FIG. 9, the lower layer 120 of the underlying layer 12 may have a convex cross-sectional shape.

In the MTJ element 1B shown in FIG. 9, the dimension of the bottom of the lower layer 120 of the underlying layer 12 in a direction parallel to substrate surface and the dimension of the lower electrode 19A in a direction parallel to the substrate surface are larger than the dimension of an upper portion of the lower layer 120.

Regarding the dimension of each layer in a direction parallel to the substrate surface, the dimension of the bottom of the lower layer 120 of the underlying layer 12 is larger than the dimensions of the upper layer 121, the storage layer 13, the intermediate layer 14, the reference layer 15, and the upper electrode 19B.

The bottom free type MTJ element 1B in FIGS. 8 and 9 is, like the MTJ element in the first embodiment, a perpendicular magnetization type MTJ element. Each of the storage layer 13 and the reference layer 15 having perpendicular magnetic anisotropy is made of a ferromagnetic material including a magnetic element in the fourth period. For example, the storage layer 13 is formed from CoFeB.

Like in the first embodiment, the first protective film 200 on the magnetic layer side of the sidewall protective film 20 in a laminated structure is formed from an insulating material including an element heavier than the magnetic element, for example, an element having an atomic number larger than the atomic number 37 as the main component. However, an element having an atomic number equal to 37 or less, more specifically, having an atomic number less than the atomic number 22 may be included in the first protective film 200 if the element is not the main component of the first protective film 200. For example, the first protective film 200 is formed from an insulating material including hafnium (Hf) as the main component. As a concrete example, like in the first embodiment, the first protective film 200 is made of a film selected from a HfBO film, HfAlBO film, ScHfBO film, HfBN film and the like.

Like in the first embodiment, the second protective film 210 on the opposite side of the magnetic layer side (interlayer insulating film side) of the sidewall protective film 20 in a laminated structure is formed from an insulating material including an element lighter than the magnetic element, for example, an element having an atomic number smaller than the atomic number 22 as the main component. For example, the second protective film 210 is formed from an insulating material including magnesium (Mg), aluminum (Al), or carbon (C) as the main component. As a concrete example, like in the first embodiment, the second protective film 210 is made of a film selected from a C film, MgAlBO film, AlBO film, ScAlBO film, MgAlBN film, CAIN film, CAlO film, CAlSiO film and the like. An element having an atomic number larger than 37 may be included in the second protective film 210 if the element is not the main element of the second protective film 210.

The MTJ element shown in FIGS. 8 and 9 may further include a shift control layer and a spacer layer.

Like in the first embodiment, the MTJ element in the second embodiment includes the sidewall protective film 20 in a laminated structure including the first and second protective films 200, 210. Accordingly, the MTJ element in the second embodiment can prevent deterioration (corrosion) of the magnetic layer originating from impurities from outside without causing degradation of characteristics of the magnetic layer originating from the sidewall protective film.

In the second embodiment, therefore, the magnetic layer can be protected from impurities during manufacturing processes and an MTJ element with improved element characteristics can be provided.

(2) Manufacturing Method

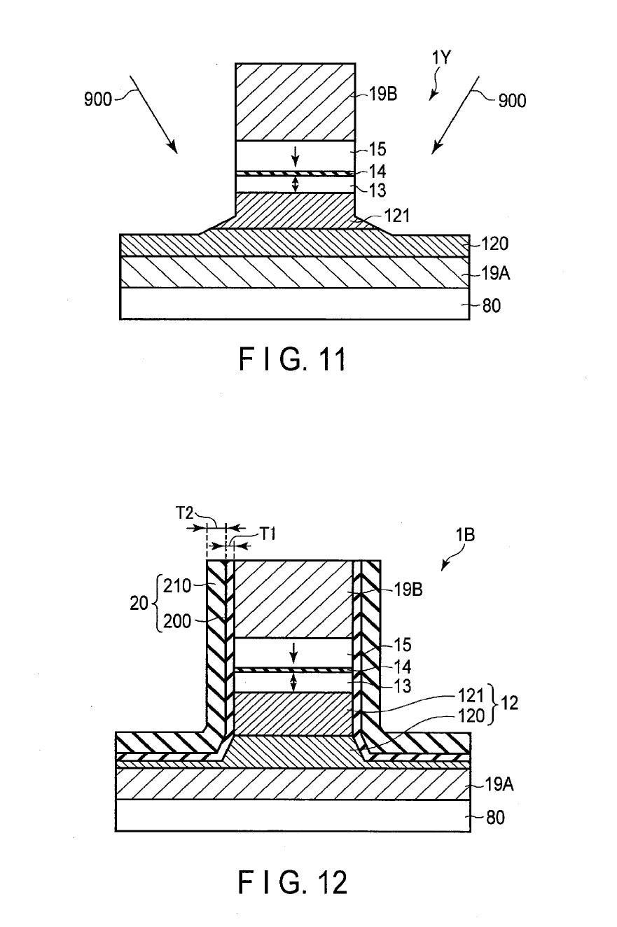

The manufacturing method of an MTJ element according to the second embodiment will be described using FIGS. 10 and 12.

FIGS. 10 and 12 are cross-sectional process charts illustrating each process of the manufacturing method of an MTJ element according to the present embodiment.

As shown in FIG. 10, the conductive layer (lower electrode) 19A, an underlying layer 12Z, the magnetic layer (storage layer) 13, the insulating layer (intermediate layer) 14, the magnetic layer (reference layer) 15, and the conductive layer 19B are successively deposited on the substrate 80 from the substrate side using the sputtering method, the ALD method or the like. For example, the underlying layer 12Z has a two-layer structure and a first film (lower layer) 120Z is formed on the conductive layer 19A and a second film (upper layer) 121Z is formed on the first film 120Z.

Accordingly, a laminated structure (layer to be processed) 1Y to form a bottom free type MTJ element is formed on the substrate 80.

As shown in FIG. 11, after the conductive layer 19B is processed into a hard mask having a pattern of a predetermined shape, ion milling using, for example, an Ar gas is performed by using the hard mask 19B as a mask while rotating the substrate.

The incidence angle of ions (ion beam) 900 in the ion milling is set to an angle (for example, about 50°) inclined with respect to the substrate surface such that debris by the ion milling should not adhere to the side face of the intermediate layer 14. Due to the inclined ion milling, the laminated structure 1Y can be processed without attachment (residual) originating from debris from layers below the intermediate layer 14 being deposited on the side face of the processed intermediate layer 14.

The laminated structure 1Y continues to be processed by the inclined ion milling until an upper portion of the underlying layer 12, for example, the upper layer 121 on the magnetic layer side is processed.

As shown in FIG. 12, the first protective film 200 having an element heavier than the magnetic element forming the magnetic layer (element having an atomic number larger than, for example, the atomic number 37) as the main component is deposited on the side face of the processed laminated structure 1B by using one of the sputtering method, ion beam sputtering method, ALD method, and CVD method while a vacuum state in the chamber is maintained.

The second protective film 210 including an element lighter than the magnetic element forming the magnetic layer (element having an atomic number smaller than, for example, the atomic number 22) as the main component is deposited on the first protective film 200 by, for example, the sputtering method so as to have the thickness T2 thicker than the thickness T1 of the first protective film 200 while a vacuum state in the chamber is maintained.

After the protective film 200 and the protective film 210 are formed, the protective films 200, 210 may undergo oxidation treatment or nitriding in the atmosphere or by plasma for more oxidation or nitriding of the film.

For example, oxidation treatment to the protective films 200, 210 is performed by exposure of the laminated structure to the atmosphere, oxidation treatment in a vacuum, radical oxidation treatment, plasma oxidation treatment, or treatment using an oxygen cluster ion. Nitriding to the protective films 200, 210 is performed by radical nitriding, plasma nitriding, or treatment using a nitrogen cluster ion. Oxidation treatment or nitriding to the protective films 200, 210 may be performed in units of layers.

Oxide, nitride, or oxynitride forming the sidewall protective film 20 only needs to ensure insulating properties without depending on a valence state (composition ratio) of composing elements of the oxide/nitride.

Accordingly, the sidewall protective film (insulator) 20 in a laminated structure is formed on the side face of the laminated structure 1B

The protective film 20, the underlying layer 12, and the lower electrode 19A between neighboring laminated structures are etched for device isolation. Then, the interlayer insulating film 81 is deposited on the substrate 80 by the CVD method such as to cover the MTJ element 1B including the sidewall protective film 20 in a laminated structure.

With each of the above processes, an MTJ element according to the second embodiment is formed.

Like in the first embodiment, the manufacturing method of an MTJ element according to the second embodiment can prevent, as described above, deterioration (corrosion) of the magnetic layer of the MTJ element caused by impurities generated during manufacturing processes by the sidewall protective film in a laminated structure including the first and second protective films 200, 210 without causing degradation of characteristics of the magnetic layer originating from the sidewall film as a protective film.

Also according to the present embodiment, the protective films 200, 210 can be formed by using film deposition technology and therefore, the degree of freedom of the selection of materials used for the protective film can be increased. Also in the present embodiment, a decrease of the degree of freedom of the material forming a magnetic tunnel junction in accordance with the material used for the protective film can be inhibited.

Therefore, according to the second embodiment, an MTJ element with improved element characteristics can be provided.

### [D] Third Embodiment

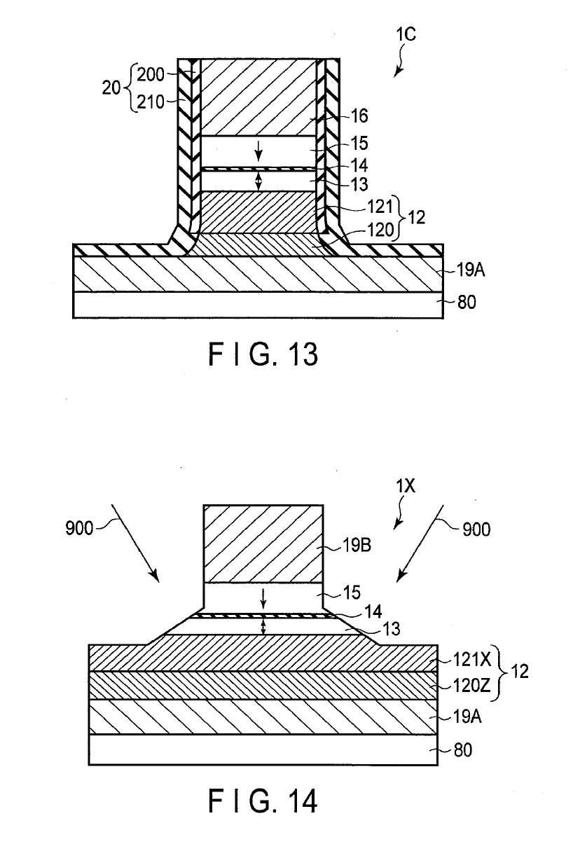

A magnetoresistive effect element according to the third embodiment and a manufacturing method thereof will be described with reference to FIGS. 13 to 16.

In the third embodiment, the description of structural elements common to those in the first and second embodiments will be provided when necessary.

The third embodiment is different from the first and second embodiments in that a sidewall protective film in a laminated structure is formed on the side face of an MTJ element by using a re-attachment generated when the laminated structure (MTJ element) is processed.

(1) Structure

The structure of the magnetoresistive effect element (MTJ element) according to the third embodiment will be described using FIG. 13.

FIG. 13 is a sectional view illustrating the structure of the MTJ element according to the present embodiment.

The MTJ element according to the third embodiment has a structure similar to that in the second embodiment.

As shown in FIG. 13, an MTJ element 10 in the present embodiment includes, like in the second embodiment, a sidewall protective film 20 in a laminated structure. The sidewall protective film 20 includes a first protective film 200 and a second protective film 210. The first and second protective films (insulating films) 200, 210 are laminated on the side face of the MTJ element 10 in a direction parallel to the surface of a substrate 80.

In the present embodiment, the first protective film 200 of the sidewall protective films 200, 210 in a laminated structure is not formed between a lower layer 120 and the second protective film 210. The second protective film 210 is in direct contact with the lower layer 120.

An underlying layer 12 in a laminated structure includes the lower layer 120 on the lower side (lower electrode side) and an upper layer 121 on the upper layer side (upper electrode side).

In the present embodiment, as will be described in the manufacturing method described later, the protective film 200 on the magnetic layer side (inner side) of a plurality of the protective films 200, 210 in the sidewall protective film 20 is formed by a re-attachment originating from debris generated by the upper layer 121 of the underlying layer 12 during processing while being oxidized or nitrided.

The upper layer 121 includes the same element as the element serving as the main component of the protective film 200. The protective film 200 in contact with the magnetic layer is formed from oxide, nitride, or oxynitride of an attachment originating from debris of the upper layer 121.

The upper layer 121 of the underlying layer 12 is formed from a material including an element heavier than the magnetic element (for example, a magnetic element in the fourth period) of the magnetic layers 13, 15, for example, an element having an atomic number larger than 37 as the main component.

For example, the upper layer 121 is a conductive film including Hf as the main component. As a concrete example of the upper layer 121 of the underlying layer 12, the upper layer 121 is formed from at least one film selected from a HfB film, HfAlB film, HfMgB film, ScHfB film and the like.

The same material as that used for the first protective film in the first embodiment is used for the first protective film 200 and the first protective film 200 is made of a film selected from a HfBO film, HfMgBO film, HfAlBO film, ScHfBO film, HfBN film and the like. However, the material of the first protective film 200 of the sidewall protective film 20 in a laminated structure in the present embodiment depends on the material used for the upper layer 121 of the underlying layer.

An element having an atomic number smaller than 22 may be included in the upper layer 121 of the underlying layer 12 and the first protective film 200 if the element is not the main element of the first protective film 200. The composition ratio of the element (for example, Hf) having an atomic number larger than 37 in the protective film 200 of the sidewall protective film 20 may be different from the composition ratio of an element having an atomic number larger than 37 in the upper layer 121 of the underlying layer 12.

The protective film 210 on the opposite side of the magnetic layer side (interlayer insulating film side) of the plurality of protective films 200, 210 in the sidewall protective film 20 is formed by a re-attachment generated from the lower layer 120 of the underlying layer 12 during etching while being oxidized, nitrided, or oxynitrided.

The lower layer 120 on the lower side (lower electrode side) of the upper layer 121 includes the same element as the element serving as the main component of the protective film 210. The protective film 210 is formed from an oxide, nitride, or oxynitride of an attachment originating from debris of the lower layer 120.

The lower layer 120 is formed from a material including an element lighter than the magnetic element (for example, a magnetic element in the fourth period) of the magnetic layers 13, 15, for example, an element having an atomic number smaller than 22 as the main component.

For example, the lower layer 120 is a conductive film including at least one element selected from a group of C, Mg, Al, and Sc as the main component. As a concrete example of the lower layer 120 of the underlying layer 12, the lower layer 120 is formed from at least one film selected from a MgAlB film, AlB film, ScAlB film, MgAlB film and the like.

For example, the same material as that used in the first embodiment is used for the second protective film 210 and the second protective film 210 is made of a film selected from a C film, MgAlBO film, AlBO film, ScAlBO film, MgAlBN film and the like. However, the material of the second protective film 210 of the sidewall protective film 20 in a laminated structure in the present embodiment depends on the material used for the lower layer 120 of the underlying layer 12.

An element having an atomic number larger than 36 may be included in the lower layer 120 of the underlying layer 12 and the second protective film 210 if the element is not the main element of the second protective film 210. The composition ratio of an element having an atomic number smaller than 22 in the protective film 210 of the sidewall protective film 20 may be different from the composition ratio of an element having an atomic number smaller than 22 in the lower layer 120 of the underlying layer 12.

(2) Manufacturing Method

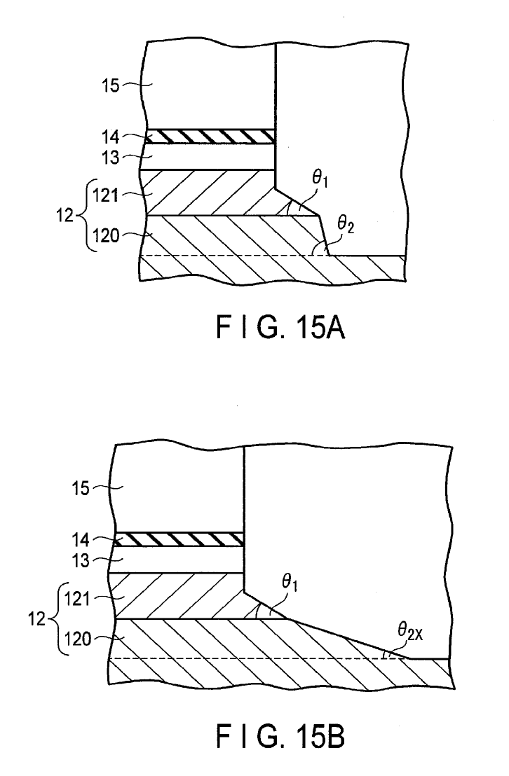

The manufacturing method of a magnetoresistive effect element (MTJ element) according to the third embodiment will be described using FIGS. 14 to 16. Each of FIGS. 14 to 16 is a cross-sectional process chart illustrating each process of the manufacturing method of an MTJ element according to the present embodiment. Here, the manufacturing method of an MTJ element in the present embodiment will be described using also FIG. 13.

As shown in FIG. 14, like the above embodiments, after a laminated structure 1X as a layer to be processed is formed on the substrate 80, ion milling to process the laminated structure 1X is performed.

The lower layer 120Z of the underlying layer 12 is formed from a material including an element lighter than the magnetic element (for example, a magnetic element in the fourth period) of the magnetic layers 13, 15, for example, an element having an atomic number smaller than 22 as the main component.

For example, the lower layer 120Z is a conductive layer including at least one element selected from a group of C, Mg, Al, and Sc as the main component. As a concrete example of the lower layer 120Z of the underlying layer 12, the lower layer film 120Z is formed from at least one film selected from a MgAlB film, AlB film, ScAlB film, MgAlB film and the like.

An upper layer 121X of the underlying layer 12 is formed from a material including an element heavier than the magnetic element (for example, a magnetic element in the fourth period) of the magnetic layers 13, 15, for example, an element having an atomic number larger than 37 as the main component.

For example, the upper layer 121X is a conductive film including Hf as the main component. As a concrete example of the upper layer 121X of the underlying layer 12, the upper layer 121 is formed from at least one film selected from a HfB film, HfAlB film, HfMgB film, ScHfB film and the like.

In the underlying layer 12 in a laminated structure, the etching rate (milling rate) of the material of the upper layer 121X is preferably slower than the etching rate of the material of the lower layer 120Z.

FIGS. 15A and 15B are diagrams showing the structure of an underlying layer when a plurality of films included in the underlying layer are formed from materials having different etching rates.

FIG. 15A shows a cross-sectional structure of the underlying layer after being processed when the etching rate of the upper layer 121 is slower than that of the lower layer 120 in the underlying layer 12 in a laminated structure. FIG. 15B shows a cross-sectional structure of the underlying layer 12 after being processed when the etching rate of the upper layer 121 is faster than that of the lower layer 120 in the underlying layer 12 in a laminated structure.

In each of the FIGS. 15A and 15B, the lower layer 120 is etched up to the same depth in a direction perpendicular to the substrate surface.

As shown in FIGS. 15A and 15B, the upper layer 121 and the lower layer 120 have taper angles θ₁, θ₂, θ₂ₓ formed between the bottom of the film and the side face of the film respectively.

If, as shown in FIG. 15A, the etching rate of the upper layer 121 is slower than that of the lower layer 120, the taper angle θ₂ of the lower layer 120 is larger than the taper angle θ₁ of the upper layer 121. This is because the lower layer 120 is removed earlier than the upper layer 121 under the same etching (milling) conditions. As a result, the spread of the taper of the lower layer 120 is smaller than that of the taper of the upper layer 121.

On the other hand, if, as shown in FIG. 15B, the etching rate of the upper layer 121 is faster than that of the lower layer 120, the taper angle θ₂ₓ of the lower layer 120 is smaller than the taper angle θ₁ of the upper layer 121. This is because the lower layer 120 is less likely to be removed than the upper layer 121 and remains on the substrate.

Thus, the dimension (taper shape spread) of the lower layer 120 in a direction parallel to the substrate surface when the etching rate of the upper layer 121 is slower than that of the lower layer 120 is smaller than the dimension of the lower layer 120 when the etching rate of the upper layer 121 is faster than that of the lower layer 120.

As shown in FIGS. 15A and 15B, it is preferable to select the material of the upper layer 121 and the material of the lower layer 120 such that the etching rate of the upper layer 121 is slower than that of the lower layer 120 under the same etching conditions to achieve a finer MTJ element.

Like in the second embodiment, a laminated structure is formed by inclined ion milling (for example, ion milling having an ion incidence angle of 50°) using Ar ions 900 so that attachment of debris on the side face of the intermediate layer is inhibited. Up to an intermediate portion of the upper layer 121X of the underlying layer 12 is processed by the inclined ion milling so that the lower layer 120Z of the underlying layer 12X is not exposed.

As shown in FIG. 16, the incidence angle of Ar ions 909 is changed from an angle inclined with respect to the substrate surface (film surface of a film included in the laminated structure) to an angle almost perpendicular to the substrate surface and ion milling from a direction perpendicular to the substrate surface is performed on the laminated structure. Hereinafter, ion milling in which the substrate surface is irradiated with ions (ion beam) from a direction almost perpendicular to the substrate surface will be called perpendicular milling.

A remaining portion of the underlying layer 12 that is not removed by the inclined ion milling is removed by the perpendicular milling. Debris originating from the underlying layer 12 processed by the perpendicular ion milling is deposited on the side face of the magnetic layer. An attachment originating from debris as described above is deposited on the side face of the magnetic layers 13, 15.

The underlying layer 12 in a laminated structure is processed from the upper portion side toward the substrate side of the laminated structure by the perpendicular milling. Thus, an attachment (for example, a film including Hf) 121R originating from the film 121 on the upper portion side of the underlying layer 12 is deposited on the side face of the laminated structure so as to be in contact with the side face of the magnetic layers 13, 15. Then, an attachment (for example, a film including at least one of C, Mg, and Al) 120R originating from the lower layer 120 of the underlying layer 12 is deposited on the attachment 121R originating from the upper layer 121.

Oxidation treatment or nitriding is performed while the attachments 121R, 1208 in a two-layer structure are deposited on the side face of a laminated structure 1Y (magnetic layers 13, 15).

As a result, as shown in FIG. 13, the attachments 121R, 120R are oxidized or nitrided and the sidewall protective film 20 including the two protective films 200, 210 having mutually different materials is formed on the side face of the processed laminated structure 1Y.

For example, the attachments 121R, 120R are oxidized by exposing the laminated structure to the atmosphere. However, the attachments 1218, 120R may be oxidized one layer at a time.

The attachments 1208, 121R may also be oxidized by oxidization treatment in a vacuum, radical oxidization treatment, plasma oxidization treatment, or treatment using an oxygen cluster ion.

The sidewall protective film 20 in a laminated structure may be formed by nitriding of the attachments 120R, 121R. For example, the attachments 120R, 121R are nitrided by radical nitriding, plasma nitriding, or treatment using a nitrogen cluster ion.

Oxide, nitride, or oxynitride forming the sidewall protective film 20 only needs to ensure insulating properties without depending on a valence state (composition ratio) of composing elements of the oxide/nitride.

To form the attachments 120R, 121R and the protective films 200, 210 having predetermined thicknesses, the thicknesses of the films 120, 121 in the underlying layer 12 and the amount of etching of the upper layer 121 of the underlying layer 12 by the inclined ion milling are controlled.

With the above process, an MTJ element according to the third embodiment is formed.

According to the present embodiment, the insulating film as a protective film of the magnetic layer can be formed by insulating attachments originating from the underlying layer. As a result, according to the present embodiment, damage of the magnetic layer originating from the formation of a protective film can be reduced.

In the present embodiment, Hf, Mg, and Al included in the sidewall protective film 20 are more likely to be oxidized than Co and Fe included in the magnetic layer. Therefore, according to the present embodiment, even if the level of oxidization is so weak that the magnetic layer is not oxidized, the films 200, 210 as good protective films can be formed on the magnetic layer.

An MTJ element according to the third embodiment and the manufacturing method thereof can provide, as described above, like in the first and second embodiments, an MTJ element with improved element characteristics.

### [E] Fourth Embodiment

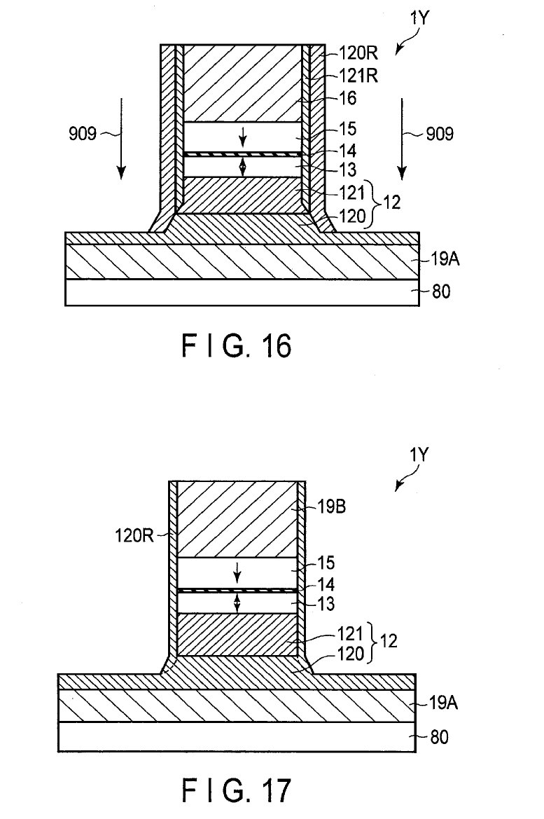

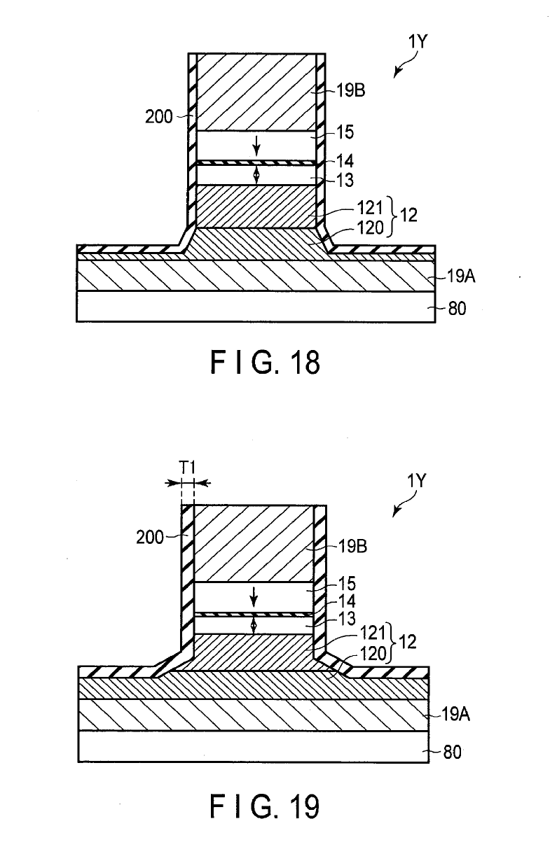

A magnetoresistive effect element according to the fourth embodiment and a manufacturing method thereof will be described with reference to FIGS. 17 and 18.

In the fourth embodiment, the description of structural elements common to those in the first to third embodiments will be provided when necessary.

The fourth embodiment is different from the first to third embodiments in that the protective film on the inner side of the sidewall protective film in a laminated structure disposed on the side face of an MTJ element (magnetic tunnel junction) is formed from a re-attachment generated during processing of a laminated structure (MTJ element) and the protective film on the outer side is formed by film deposition technology.

(1) Structure

The structure of an MTJ element 10 according to the fourth embodiment will be described.

The structure of the MTJ element in the present embodiment is similar to that of the MTJ element in the third embodiment. The structure of the MTJ element according to the present embodiment will be described using FIG. 13.

An MTJ element 1C according to the fourth embodiment includes an underlying layer 12 in a laminated structure and a sidewall protective film 20 in a laminated structure.

A film 200 on the magnetic layer side (inner side) of the sidewall protective film 20 in a laminated structure is formed from an attachment originating from debris of a lower layer 120 of the underlying layer 12 during processing.

The element of the main component included in the lower layer 120 is the same as that of the main component included in the protective film 200 on the inner side of the sidewall protective film 20.

The lower layer 120 is formed from a material including an element heavier than a magnetic element in the fourth period, for example, an element having an atomic number larger than 37 as the main component. For example, the lower layer 120 is a conductive film including Hf as the main component. As a concrete example of the lower layer 120 of the underlying layer 12, the lower layer 120 is formed from at least one film selected from a group of HfB, HfAlB, HfMgB, ScHfB and the like.

The protective film 200 in contact with magnetic layers 13, 15 of the sidewall protective film 20 in a laminated structure is an oxide, nitride, or oxynitride formed from an attachment originating from debris of the lower layer 120 of the underlying layer 12. Like the above embodiments, the protective film 200 is a film (for example, an insulating film) formed from an oxide, nitride, or oxynitride including Hf as the main component.

In the present embodiment, the protective film 200 may be a film (for example, an insulating film) formed from an attachment originating from debris of the upper layer 121 of the underlying layer 12.

A protective film 210 not in contact with the magnetic layers 13, 15 of the sidewall protective film 20 in a laminated structure is a film formed by film deposition technology such as the sputtering method.

(2) Manufacturing Method

The manufacturing method of an MTJ element according to the fourth embodiment will be described using FIGS. 17 and 18. FIGS. 17 and 18 are cross-sectional process charts illustrating the manufacturing method of an MTJ element according to the present embodiment.

The manufacturing method of an MTJ element according to the present embodiment will be described using also FIGS. 9, 10, and 12 when appropriate.

Like the above embodiments, as shown in FIG. 9, a laminated structure to form an MTJ element is formed on a substrate 80. In the present embodiment, the lower layer 120 on the lower electrode side of the underlying layer 12 is formed from a material including an element heavier than a magnetic element (for example, Co or Fe) in the fourth period forming the magnetic layer 13, for example, an element (for example, Hf) having an atomic number larger than 37 as the main component. Then, the laminated structure is processed by the inclined ion milling based on a hard mask.

As shown in FIG. 10, the inclined ion milling is performed until the top surface of the lower layer 120 in contact with a lower electrode 19A of the underlying layer 12 in a laminated structure is exposed.

A laminated structure 1Y is processed by the inclined ion milling without debris originating from the upper layer 121 of the underlying layer 12 being attached to the processed magnetic layers 13, 15 and an intermediate layer 14.

As shown in FIG. 17, the perpendicular ion milling is performed while the top surface of the lower layer 120 including an element (for example, Hf) having an atomic number larger than 37 as the main component is exposed.

Accordingly, debris of the lower layer 120 attaches to the processed surface of the laminated structure 1Y and an attachment 120R made of substantially the same material as that of the lower layer 120 is deposited on the side face of the processed magnetic layers 13, 15 and the intermediate layer 14.

While the attachment 120R including an element with an atomic number larger than 37 as the main component is deposited on the side face of the magnetic layers 13, 15 and the intermediate layer 14, like in the third embodiment, oxidization treatment or nitriding is performed. The attachment 120R is thereby insulated.

As a result, as shown in FIG. 18, the protective film 200 including an element with an atomic number larger than 37 as the main component is formed so as to be in contact with the magnetic layers 13, 15. The protective film 200 is an oxide film or nitride film including Hf as the main component. The protective film 200 is formed so as to have a thickness of about 1 to 3 nm.

For example, oxidization of the attachment 120R is performed by exposing the laminated structure to the atmosphere. The attachment 120R may also be oxidized by oxidization treatment in a vacuum, radical oxidization treatment, plasma oxidization treatment, or treatment using an oxygen cluster ion. The protective film 200 may also be formed by nitriding of the attachment 120R. For example, the attachment 120R is nitrided by radical nitriding, plasma nitriding, or treatment using a nitrogen cluster ion.

Then, the protective film 210 including an element lighter than a magnetic element in the fourth period, for example, an element having an atomic number smaller than 22 (for example, C, Mg, Al, or Sc) as the main component is formed on the laminated structure 1Y by using the sputtering method, CVD method or the like via the protective film 200 to cover the side face of the magnetic layers 13, 15.

With the above process, an MTJ element according to the fourth embodiment is formed.

The oxide, nitride, or oxynitride forming the sidewall protective film 20 only needs to ensure insulating properties, regardless of a valence state (composition ratio) of composing elements of the oxide/nitride.

The protective film 200 on the inner side of the sidewall protective film 20 in a laminated structure may be formed by performing insulation processing of an attachment originating from debris of the upper layer 121 on the upper electrode side of the underlying layer 12 in a laminated structure. In this case, the upper layer 121 is formed from a material including an element with an atomic number larger than 37 (for example, Hf) as the main component.

An MTJ element according to the fourth embodiment and the manufacturing method thereof can provide, as described above, like in the first to third embodiments, an MTJ element with improved element characteristics.

### [F] Fifth Embodiment

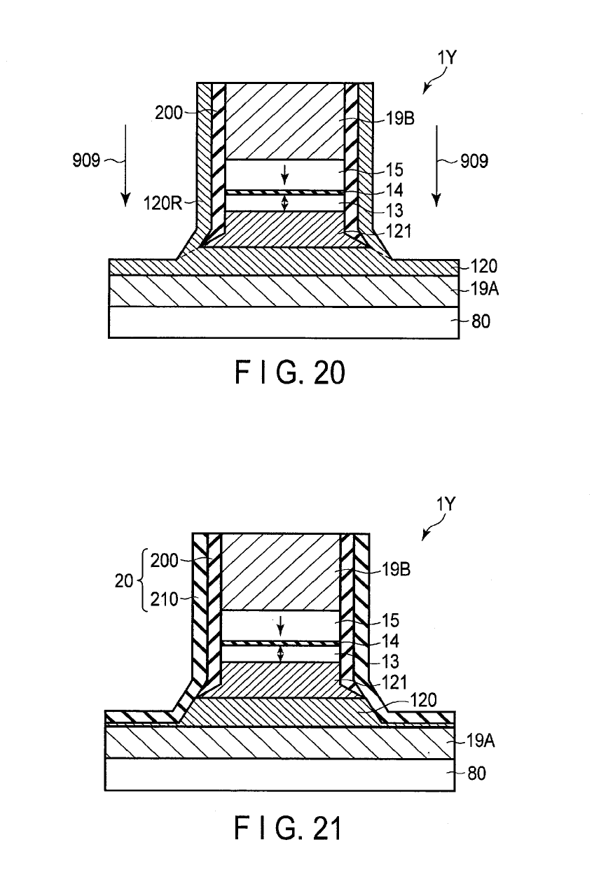

Hereinafter, a magnetoresistive effect element according to the fifth embodiment and a manufacturing method thereof will be described with reference to FIGS. 19 to 21.

In the present embodiment, the description of structural elements common to those in the first to fourth embodiments will be provided when necessary.

The fifth embodiment is different from the first to fourth embodiments in that the protective film on the inner side of the sidewall protective film in a laminated structure disposed on the side face of an MTJ element is formed by film deposition technology and the protective film on the outer side is formed from a re-attachment generated during processing of a laminated structure (MTJ element).

(1) Structure

The structure of the MTJ element (magnetoresistive element) according to the fifth embodiment will be described.

The structure of the MTJ element in the present embodiment is similar to that of the MTJ element in the third embodiment. The structure of the MTJ element according to the present embodiment will be described using FIG. 13.

As shown in FIG. 13, an MTJ element 1C in the fifth embodiment includes, like in the first to fourth embodiments, an underlying layer 12 in a laminated structure and a sidewall protective film 20 in a laminated structure.

The element of the main component included in a lower layer 120 of the underlying layer 12 is the same as that of the main component included in a protective film 210 on the outer side of the sidewall protective film 20.

The protective film 210 on the outer side (interlayer insulating film side) of the sidewall protective film 20 is formed from oxide, nitride, or oxynitride of an attachment originating from debris of the lower layer 120.

The element of the main component included in the lower layer 120 is the same as that of the main component included in the protective film 210 on the outer side of the sidewall protective film 20.

The lower layer 120 is formed from a material including an element lighter than a magnetic element in the fourth period, for example, an element having an atomic number smaller than 22 as the main component. For example, the lower layer 120 is a conductive film including at least one element selected from C, Mg, Al, and Sc as the main component. As a concrete example of the lower layer 120 of the underlying layer 12, the lower layer 120 is formed from at least one film selected from a group of a MgAlB film, AlB film, ScAlB film, MgAlB film and the like.

The protective film 210 not in contact with magnetic layers of the sidewall protective film 20 in a laminated structure is an oxide film, nitride film, or oxynitride film formed from an attachment originating from debris of the lower layer 120 of the underlying layer 12. Like the above embodiments, the protective film 210 is an insulating film formed from an oxide, nitride, or oxynitride including at least one of C, Mg, Al, and Sc as the main component.

In the present embodiment, the protective film 210 may be an insulating film (protective film) formed from an attachment originating from debris of the upper layer 121 of the underlying layer 12.

(2) Manufacturing Method

The manufacturing method of an MTJ element according to the fifth embodiment will be described using FIGS. 19 and 21. FIGS. 19 and 21 are cross-sectional process charts illustrating the manufacturing method of an MTJ element according to the present embodiment.

Here, the manufacturing method of an MTJ element in the present embodiment will be described using also FIG. 10 when appropriate.

Like the above embodiments, as shown in FIG. 10, a laminated structure 1Y to form an MTJ element is formed on a substrate 80. In the present embodiment, the lower layer 120 on the lower electrode side of the underlying layer 12 is formed from a material including an element lighter than a magnetic element (for example, Co or Fe) in the fourth period forming a magnetic layer 13, for example, an element having an atomic number smaller than 22 (for example, C, Mg, Al, or Sc) as the main component. Then, the laminated structure 1Y is processed by the inclined ion milling based on a hard mask.

The inclined ion milling is performed until the top surface of the lower layer 120 in contact with a lower electrode 19A of the underlying layer 12 in a laminated structure is exposed.

As shown in FIG. 19, the laminated structure 1Y is processed by the inclined ion milling without debris originating from the upper layer 121 and the lower layer 120 of the underlying layer 12 being attached to the processed magnetic layers 13, 15 and an intermediate layer 14.

The first protective film (for example, an insulating film including Hf as the main component) 200 with an atomic number larger than 37 as the main component is deposited on the side face of the processed magnetic layers 13, 15 and the intermediate layer 14 by, for example, the sputtering method and the like. The protective film 200 is deposited on an exposed surface of the lower layer 120.

As shown in FIG. 20, the protective film 200 on the lower layer 120 is removed by the inclined ion milling in which the incidence angle of an ion beam is set to about 50° so that the top surface of the lower layer 120 is exposed and then the lower layer 120 is exposed.

The thickness of the protective film 200 on the side face of the magnetic layers 13, 15 may be made thinner by the inclined ion milling. The thinned protective film 200 has a thickness of about 1 to 3 nm. In consideration of the possibility that the protective film 200 is made thinner during the manufacturing process, it is preferable that the protective film 200 is deposited.

The lower layer 120 including an element with an atomic number smaller than 22 (for example, C, Mg, Al, or Sc) as the main component is etched by the perpendicular ion milling 909. Debris of the lower layer 120 etched by the perpendicular ion milling is attached onto the first protective film 200.

As a result, an attachment 120R originating from debris of the lower layer 120 is deposited on the first protective film 200.

Oxidization treatment or nitriding is performed while the attachment 120R is attached to the first protective film 200. For example, oxidization of the attachment 1208 is performed by exposing the laminated structure to the atmosphere. The attachment 120R may also be oxidized by oxidization treatment in a vacuum, radical oxidization treatment, plasma oxidization treatment, or treatment using an oxygen cluster ion. The protective film 200 may also be formed by nitriding of the attachment 120R. For example, the attachment 120R is nitrided by radical nitriding, plasma nitriding, or treatment using a nitrogen cluster ion.

Accordingly, as shown in FIG. 21, the attachment 120R is insulated and the protective film 210 including an element having an atomic number smaller than 22 (for example, at least one of C, Mg, and Al) as the main component is formed on the protective film 200 having an atomic number larger than 37 as the main component.

With the above manufacturing process, an MTJ element according to the fifth embodiment is formed.

The oxide, nitride, or oxynitride forming the sidewall protective film 20 only needs to ensure insulating properties without depending on a valence state (composition ratio) of composing elements of the oxide/nitride.

The inclined ion milling to remove the first protective film 200 on the lower layer 120 may be omitted. In such a case, the protective film 200 on the lower layer 120 is removed by the perpendicular ion milling. Debris of the etched first protective film 200 is attached onto the protective film 200 on the side face of the magnetic layers 13, 15. The thickness of the protective film 200 on the side face of the magnetic layers 13, 15 increases with attachment of debris of the protective film 200. Thus, the thickness of the protective film 200 during deposition is preferably controlled by considering that the thickness of the protective film 200 is increased by an attachment.

When the top surface of the upper layer 121 of the underlying layer is exposed, etching of the laminated structure may once be stopped to allow the first protective film 200 to deposit on the side face of the magnetic layers 13, 15.

According to the manufacturing method of an MTJ element according to the fifth embodiment, as described above, like in the first to fourth embodiments, an MTJ element with improved element characteristics can be provided.

### [G] Sixth Embodiment

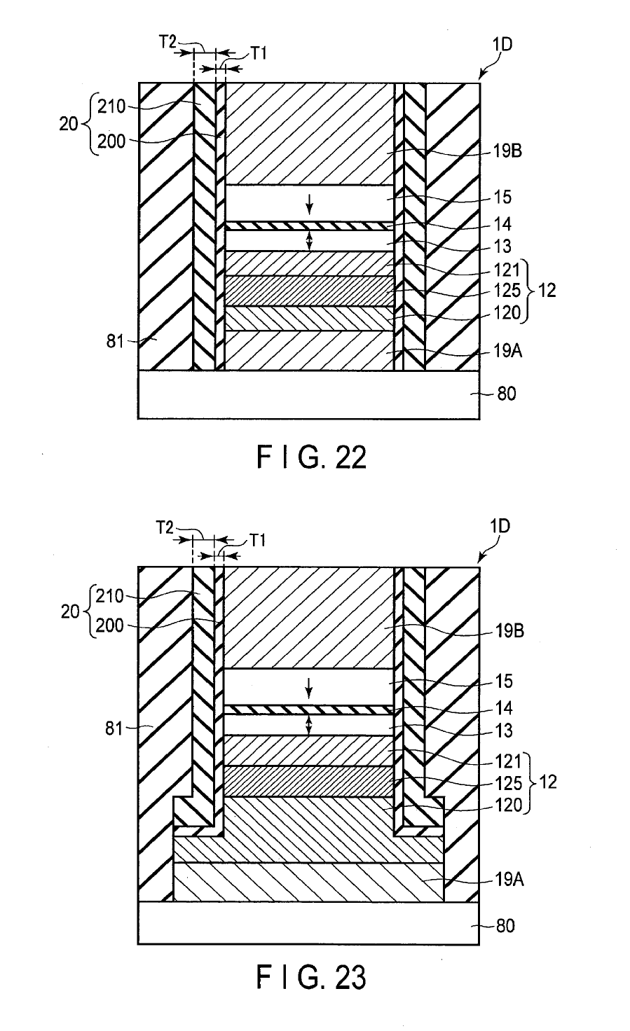

The manufacturing method of a magnetoresistive effect element (MTJ element) according to the sixth embodiment will be described using FIGS. 22 and 23.

In the present embodiment, the description of structural elements common to those in the first to fifth embodiments will be provided when necessary.

An MTJ element 1D according to the sixth embodiment is different from an MTJ element according to the first to fifth embodiments in that an underlying layer in a three-layer structure is provided.

FIGS. 22 and 23 are sectional views illustrating the structure of the MTJ element according to the present embodiment.

As shown in FIGS. 22 and 23, an underlying layer 12 includes a lower layer 120 on the lower electrode side, an upper layer 121 on the upper electrode side, and a middle layer 125 between the lower layer 120 and the upper layer 121.

The lower layer 120 is in contact with a lower electrode 19A and the upper layer 121 is in contact with a storage layer 13.

To omit the lower electrode, the underlying layer 12 in a three-layer structure may be used as a lower electrode.

A sidewall protective film 20 in a laminated structure is disposed on the side face of a magnetic tunnel junction including the storage layer 13, a reference layer 15, and an intermediate layer 14.

In the example in FIG. 22, the sidewall protective film 20 covers the entire side face of the underlying layer 12 in a three-layer structure. In the example in FIG. 23, the film 120 of the lowest layer of the underlying layer in the three-layer structure has a convex cross-sectional shape. The side face on the upper portion side of the lower layer 120 is covered with the sidewall protective film 20 and the side face on the bottom side of the lower layer 120 is covered with an interlayer insulating film 81. The middle layer 125 of the underlying layer in the three-layer structure is covered with the sidewall protective film 20.

A first protective film 200 is a film including an element heavier than the magnetic element (element having an atomic number larger than that of the magnetic element) forming the magnetic layer. A second protective film 210 is a film including an element lighter than the magnetic element (element having an atomic number smaller than that of the magnetic element) forming the magnetic layer.

If, for example, the magnetic layer is formed from a film including a magnetic element in the fourth period, the film 200 including an element heavier than the magnetic element as the main component is the protective film 200 including an element having an atomic number larger than 37, for example, Hf. If the magnetic layer is formed from a film including a magnetic element in the fourth period, the film 210 including an element lighter than the magnetic element as the main component is the protective film 210 including an element having an atomic number smaller than 22, for example, at least one element selected from C, Mg, and Al.

Each of the first and second protective films 200 is formed by, for example, the sputtering method, ALD method, or the like.

When, as described above, the protective film 200 on the inner side included in the sidewall protective film on the side face of the magnetic layer is formed by a re-attachment originating from etching of the underlying layer 12 which is insulated, one film selected from the three films 120, 121, 125 in the underlying layer 12 includes as the main component an element with an atomic number larger than the atomic number 37 as the main component of the protective film 200.

When, as described above, the protective film 210 on the outer side included in the sidewall protective film on the side face of the magnetic layer is formed by a re-attachment originating from etching of the underlying layer 12 which is insulated, one film selected from the three films 120, 121, 125 in the underlying layer 12 includes as the main component an element with an atomic number smaller than the atomic number 22 as the main component of the protective film 210.

If both of the two protective films 200, 210 in the sidewall protective film 20 are formed from a re-attachment of the films in the underlying layer in a three-layer structure, one film of the upper layer 121 and the middle layer 125 in the underlying layer is formed from a film including an element heavier than the magnetic element as the main component. In this case, the films 125, 120 on the lower electrode side than the film 121 including an element heavier than the magnetic element as the main component are formed from a film including an element lighter than the magnetic element as the main component.

For example, oxidization of an attachment originating from etching of the underlying layer in a three-layer structure is performed by exposing the laminated structure to the atmosphere. However, the attachments 121R, 120R may be oxidized one layer at a time.

The attachment originating from the underlying layer in a three-layer structure may also be oxidized by oxidization treatment in a vacuum, radical oxidization treatment, plasma oxidization treatment, or treatment using an oxygen cluster ion. The sidewall protective film 20 in a laminated structure may be formed by nitriding of the attachment.

For example, the attachment is nitrided by radical nitriding, plasma nitriding, or treatment using a nitrogen cluster ion.

The oxide, nitride, or oxynitride forming the sidewall protective film only needs to ensure insulating properties, regardless of a valence state (composition ratio) of composing elements of the oxide/nitride.

For example, the upper layer 121 in contact with the magnetic layer 13 may be used as a functional layer to improve crystallinity and characteristics of the magnetic layer and the middle layer 125 and the lower layer 120 may be used as source layers of attachment to form the films 200, 210 in the sidewall protective film 20.

By using the underlying layer 12 including two or more films 120, 121, 125 as described above, the sidewall protective film 20 including a plurality of the films 200, 210 made of mutually different materials can be formed from attachments originating from debris of the underlying layer 12 and also provided the underlying layer to improve characteristics of the magnetic layer in the MTJ element.

### [H] Modification

A modification of the magnetoresistive effect element (MTJ element) according to the present embodiment will be described.

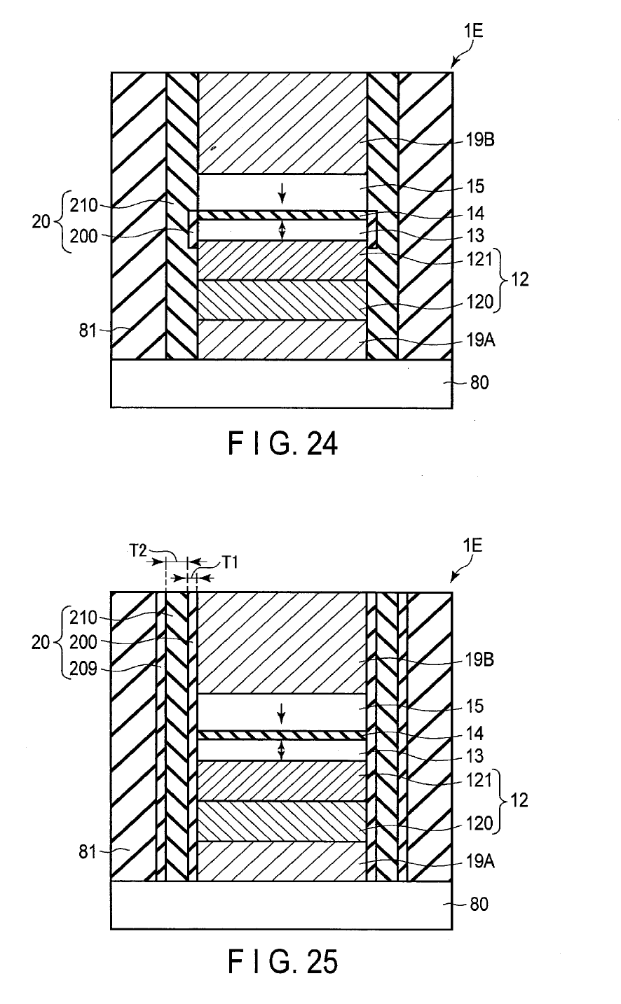

FIGS. 24 and 25 are sectional views showing a modification of the MTJ element according to the present embodiment.

As shown in FIG. 24, in an MTJ element 1E according to the modification, the protective film 200 including an element heavier than the magnetic element of the two protective films 200, 210 included in the sidewall protective film 20 in a laminated structure may be disposed on the side face of at least the magnetic layer 13.

In this case, the side face of the reference layer 15 and the intermediate layer 14 is in contact with the protective film 210 including an element lighter than the magnetic element.

As shown in FIG. 25, the sidewall protective film 20 in a laminated structure in the MTJ element 1E according to the modification may have a three-layer structure.

For example, an insulating film 209 made of a silicon nitride film may be disposed between the interlayer insulating film 81 and the film 210 including an element lighter than the magnetic layer as a protective film.

Also, a film including both of an element heavier than the magnetic element and an element lighter than the magnetic element may be disposed between the film 200 including an element heavier than the magnetic element and the film 210 including an element lighter than the magnetic element.

Substantially the same effect as that of the above embodiments is achieved by the MTJ element according to the modification shown in FIGS. 24 and 25.

### [I] Application Example

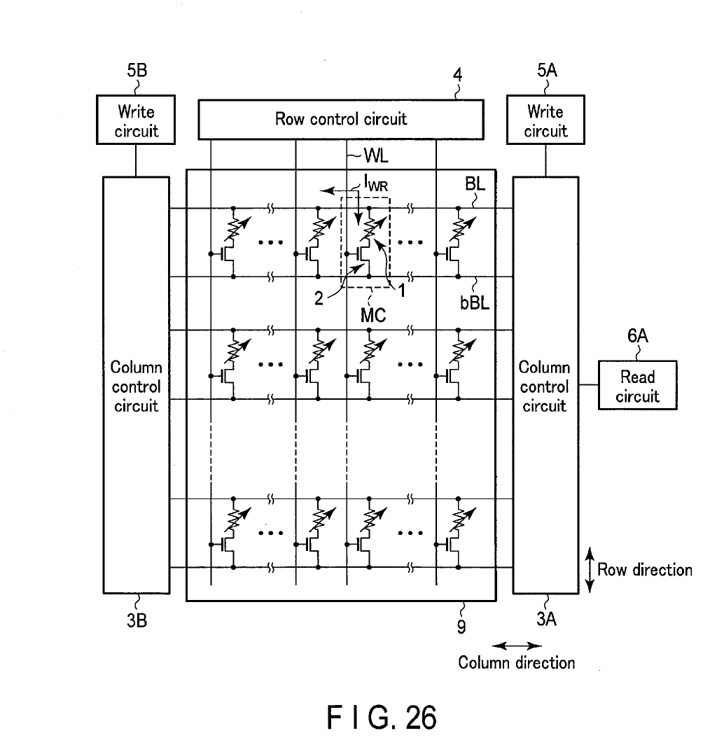

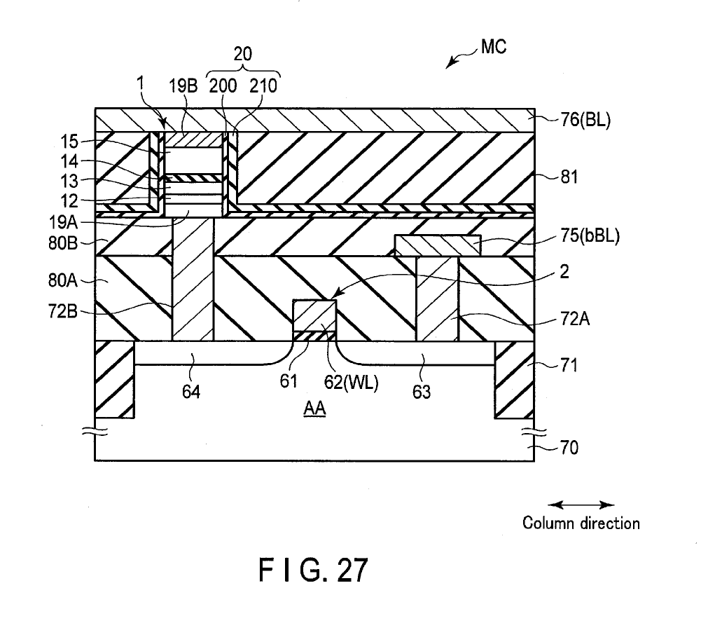

An application example of the magnetoresistive element according to an embodiment will be described with reference to FIGS. 26 and 27.

The same reference signs are attached to substantially the same components as those described in the above embodiments and the description thereof is provided when necessary.

The magnetoresistive element in the above embodiments is used as a magnetic memory, for example, as a memory element of MRAM (Magnetoresistive Random Access Memory). In the present application example, an STT type MRAM (Spin-torque transfer MRAM) is illustrated.

FIG. 26 is a diagram showing a circuit configuration of a memory cell array of MRAM and a neighborhood thereof.

As shown in FIG. 26, a memory cell array 9 includes a plurality of memory cells MC.

The plurality of memory cells MC are arranged in the memory cell array 9 like an array. A plurality of bit lines BL, bBL and a plurality of word lines WL are disposed in the memory cell array 9. The bit lines BL, bBL extend in the column direction. The word line WL extends in the row direction. The two bit lines BL, bBL form a bit line pair.

The memory cell MC is connected to the bit lines BL, bBL and the word line WL.

A plurality of memory cells MC arranged in the column direction are connected to the common bit line pair BL, bBL. A plurality of memory cells MC arranged in the row direction are connected to the common word line WL.

The memory cell MC includes, for example, a magnetoresistive element (MTJ element) 1 as a memory element and a selection switch 2. The magnetoresistive element (MTJ element) 1 described in the first to sixth embodiments or the modification is used as the MTJ element 1 in the memory cell MC.

The selection switch 2 is, for example, a field effect transistor. Hereinafter, the field effect transistor as the selection switch 2 will be called the selection transistor 2.

One end of the MTJ element 1 is connected to the bit line BL and the other end of the MTJ element 1 is connected to one end (source/drain) of a current path of the selection transistor 2. The other end (drain/source) of the current path of the selection transistor 2 is connected to the bit line bBL. A control terminal (gate) of the selection transistor 2 is connected to word line WL.

One end of the word line WL is connected to a row control circuit 4. The row control circuit 4 controls activation/deactivation of the word line based on an address signal from outside.

Column control circuits 3A, 3B are connected to one end and the other end of the bit lines BL, bBL.

The column control circuits 3A, 3B control activation/deactivation of the bit lines BL, bBL based on an address signal from outside.

Write circuits 5A, 5B are connected to one end and the other end of the bit lines BL, bBL via the column control circuits 3A, 3B respectively. The write circuits 5A, 5B each include a source circuit such as a current source or a voltage source to generate a write current I_{WR} and a sink circuit to absorb the write current.

In an STT type MRAM, the write circuits 5A, 5B supply the write current I_{WR} to the memory cell selected from outside (hereinafter, called the selected cell) while data is written.

When data is written into the MTJ element 1, the write circuits 5A, 5B bidirectionally pass the write current I_{WR} to the MTJ element 1 in the memory cell MC in accordance with data to be written into the selected cell. That is, the write current I_{WR} from the bit line BL to the bit line bBL or the write current I_{WR} from the bit line bBL to the bit line BL is output from the write circuits 5A, 5B in accordance with data to be written into the MTJ element 1.

A read circuit 6A is connected to the bit lines BL, bBL via the column control circuit 3A. The read circuit 6A includes a voltage source or a current source to generate a read current, a sense amplifier that detects and amplifies a read signal, and a latch circuit that temporarily holds data. When data is read from the MTJ element 1, the read circuit 6A supplies a read current to the selected cell. The current value of a read current is smaller than that of a write current (magnetization reversal threshold) so that the magnetization of the storage layer cannot be reversed by the read current.

The current value or the potential of a read node differs according to the magnitude of resistance of the MTJ element 1 to which a read current is supplied. Data stored by the MTJ element 1 is determined based on variations (read signal, read output) corresponding to the magnitude of the resistance.

In the example shown in FIG. 26, the read circuit 6A is disposed on one end side in the column direction of the memory cell array 9, but two read circuits may be disposed at one end and the other end in the column direction of the memory cell array 9.

For example, a buffer circuit, a state machine (control circuit), an ECC (Error Checking and Correcting) circuit and the like may be disposed in the same chip as the memory cell array 9.

FIG. 27 is a sectional view showing an example of the structure of the memory cell MC disposed in the memory cell array 9 of the MRAM of the present application example.

The memory cell MC is formed in an active area AA of a semiconductor substrate 70. The active area AA is partitioned by an insulating film 71 embedded in a device isolation area of the semiconductor substrate 70.

The surface of the semiconductor substrate 70 is covered with interlayer insulating films 80A, 80B, 81.

The MTJ element 1 is disposed in the interlayer insulating film 81. The top end of the MTJ element 1 is connected to a bit line 76 (BL) via an upper electrode 19B. The bottom end of the MTJ element 1 is connected to a source/drain diffusion layer 64 of the selection transistor 2 via the lower electrode 19A and a contact plug 72B embedded in the interlayer insulating films 80A, 80B. A source/drain diffusion layer 63 of the selection transistor 2 is connected to a bit line 75 (bBL) via a contact plug 72A in the interlayer insulating film 80A.

A gate electrode 62 is disposed on the surface of the active area AA between the source/drain diffusion layer 64 and the source/drain diffusion layer 63 via a gate insulating film 61. The gate electrode 62 extends in the row direction and is used as the word line WL.

The MTJ element 1 is disposed immediately above the plug 72B. However, the MTJ element 1 may be arranged in a position deviating from the position (for example, above the gate electrode of the selection transistor) immediately above the contact plug by using an interconnect.

In FIG. 27, an example in which a memory cell is disposed in one active area AA is shown. However, two memory cells adjacent to each other in the column direction may be disposed in one active area AA such that the two memory cells share one bit line bBL and the source/drain diffusion layer 63. The cell size of the memory cell MC is thereby reduced.

In FIG. 27, a field effect transistor in a planar structure is shown as the selection transistor 2, but the structure of the field effect transistor is not limited to the above case. For example, a field effect transistor in a three-dimensional structure such as an RCAT (Recess Channel Array Transistor) and FinFET may also be used as the selection transistor. An RCAT has a structure in which the gate electrode is embedded in a recess in a semiconductor area via a gate insulating film. A FinFET has a structure in which the gate electrode intersects with a semiconductor area (fin) having a stripe shape via a gate insulating film.

The MTJ element 1 according to an embodiment selected from a plurality of the above embodiments is used as a memory element of an MRAM. The MTJ element 1 in the memory cell MC includes the sidewall protective film 20 having a laminated structure. The sidewall protective film 20 includes the first protective film (insulating film) 200 including an element (for example, Hf) having an atomic number larger than that of the magnetic element (for example, Co or Fe) as the main component and the second protective film (insulating film) 210 including an element (for example, at least one of Mg, Al, B, and C) having an atomic number smaller than that of the magnetic element as the main component. The MTJ element according to the present embodiment is protected from oxygen and moisture generated during the manufacturing process after the MTJ element is formed by the sidewall protective film 20 in a laminated structure without deterioration of characteristics of the magnetic layers 13, 15 originating from the sidewall protective film 20.

The MTJ element 1 according to the present embodiment can inhibit an increase of the coercive force of the storage layer 13 and the damping constant originating from contact of the protective film and the storage layer and thus, an increase of the write current can be inhibited.

Therefore, a magnetic memory including a magnetoresistive element according to an embodiment can improve operation characteristics.

### [J] Others

In a magnetoresistive element in the above embodiments, a magnetoresistive effect element using a perpendicular magnetization film is illustrated. However, if the first protective film 200 including an element (for example, Hf) having an atomic number larger than that of the magnetic element (for example, Co or Fe) and the second protective film 210 including an element (for example, at least one of Mg, Al, and C) having an atomic number smaller than that of the magnetic element are disposed on the side face of the magnetic layers 13, 15 in the order from the side face side of the MTJ element to the interlayer insulating film side, a parallel magnetization film (in-plane magnetization film) in which the direction of magnetization of the magnetic layer is parallel to the film surface may also be used for an MTJ element according to an embodiment. An MTJ element of parallel magnetization type using a parallel magnetization film can obtain effects similar to those described in the embodiments.

A magnetoresistive element according to an embodiment may also be applied to magnetic memories other than MRAM.

A magnetic memory using a magnetoresistive element according to an embodiment is used as an alternative memory of DRAM, SRAM and the like. A magnetic memory using a magnetoresistive element according to an embodiment is used as a cache memory of a storage device like, for example, SSD (Solid State Drive).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive effect element comprising:
a first magnetic layer in which a direction of magnetization is variable, the first magnetic layer including a first magnetic element;
a second magnetic layer in which the direction of magnetization is invariable;
an intermediate layer between the first magnetic layer and the second magnetic layer; and
a sidewall layer having a laminated structure on a side face of the first magnetic layer,
wherein the sidewall layer includes
a first layer disposed on the side face of the first magnetic layer and including a first element having an atomic number larger than an atomic number of the first magnetic element, and
a second layer disposed on the first layer and including a second element having an atomic number smaller than the atomic number of the first magnetic element, the first layer disposed between the first magnetic layer and the second layer.

2. The element of claim 1, wherein
the atomic number of the first element is larger than 37, and
the atomic number of the second element is smaller than 22.

3. The element of claim 1, wherein
the first element is Hf, and
the second element is at least one element selected from a group consisting of C, Mg, and Al.

4. The element of claim 3, wherein
the first layer is an insulating layer including Hf, and
the second layer is an insulating layer including at least one of C, Mg, and Al.

5. The element of claim 1, wherein
a thickness of the first layer is 3 nm or less, and
the thickness of the second layer is larger than the thickness of the first layer.

6. The element of claim 1, wherein a thickness of the second layer is 20 nm or less.

7. The element of claim 1, wherein a thickness of the second layer is 20 nm or more and 30 nm or less.

8. The element of claim 1, further comprising:
a third layer which comprises a first conductive layer including the first element, the first magnetic layer disposed between the third layer and the intermediate layer.

9. The element of claim 1, further comprising:
a fourth layer which comprises a second conductive layer including the second element, the first magnetic layer disposed between the fourth layer and the intermediate layer.

10. The element of claim 8, further comprising:
a fourth layer which comprises a second conductive layer including the second element, the third layer disposed between the fourth layer and the the first magnetic layer.

11. The element of claim 1, further comprising: an interlayer insulating layer covering the side face of the sidewall layer,
wherein the second layer is disposed between the interlayer insulating layer and the first layer.

12. A magnetic memory comprising:
a memory cell including the magnetoresistive effect element of claim 1.

13. A manufacturing method of a magnetoresistive effect element comprising:
forming an underlying layer on a substrate;
forming a laminated structure on the underlying layer, the laminated structure including a first magnetic layer, a second magnetic layer, and an intermediate layer between the first magnetic layer and the second magnetic layer;
processing at least the first magnetic layer of the laminated structure;
forming a first layer including a first element on a side face of the first magnetic layer processed, the first element having an atomic number larger than an atomic number of a first magnetic element included in the first magnetic layer; and
forming a second layer including a second element on the first layer, the second element having an atomic number smaller than the atomic number of the first magnetic element included in the first magnetic layer.

14. The manufacturing method of claim 13, further comprising:
insulating each of the first and second layers.

15. The manufacturing method of claim 13, further comprising:
forming the underlying layer such that a first conductive layer including the first element is included in the underlying layer;
attaching the first layer to the side face of the first magnetic layer by processing the first conductive layer; and
insulating the first layer attached to the side face of the first magnetic layer.

16. The manufacturing method of claim 13, further comprising:
forming the underlying layer such that a second conductive layer including the second element is included in the underlying layer;
attaching the second layer to the first layer by processing the second conductive layer; and
insulating the first layer and the second layer sequentially or simultaneously.

17. The manufacturing method of claim 13, wherein
the underlying layer includes a first portion on a side of the substrate and a second portion on a side of the laminated structure, and
an etching rate of the second portion is slower than the etching rate of the first portion under a first etching condition.

18. The manufacturing method of claim 13, wherein
a thickness of the second layer is larger than a thickness of the first layer.

19. The manufacturing method of claim 13, wherein
the atomic number of the first element is larger than 37, and
the atomic number of the second element is smaller than 22.

20. The manufacturing method of claim 13, wherein
the first element is Hf, and
the second element is at least one element selected from a group consisting of C, Mg, and Al.
